(19) United States
(12) Patent Application Publication
(10) Pub. No.: US 2016/0068952 A1
(43) Pub. Date: Mar. 10, 2016

(54) SUBSTRATE PROCESSING APPARATUS AND GAS DISTRIBUTION ASSEMBLY THEREOF

(71) Applicant: HITACHI KOKUSAI ELECTRIC INC., Tokyo (JP)

(72) Inventor: Takafumi SASAKI, Toyama-shi (JP)

(73) Assignee: HITACHI KOKUSAI ELECTRIC INC., Tokyo (JP)

(21) Appl. No.: 14/670,832

(22) Filed: Mar. 27, 2015

(30) Foreign Application Priority Data
Sep. 10, 2014 (JP) 2014183916

(51) Int. Cl. C23C 16/44; C23C 16/458; C23C 16/455

(52) U.S. Cl. CPC C23C 16/4412; C23C 16/455; C23C 16/458

(57) ABSTRACT

A substrate processing apparatus and a gas distribution assembly thereof are disclosed. A substrate processing apparatus includes a susceptor configured to place a substrate on it, a process gas distribution assembly configured to supply a process gas on a surface of the substrate from the upper side of the susceptor and an inert gas distribution assembly arranged next to the process gas distribution assembly, configured to supply an inert gas on the surface of the substrate from the upper side of the susceptor. The substrate processing apparatus further includes a gas exhausting system, the gas exhausting system has a gas exhausting aperture defined between the process gas distribution assembly and the inert gas distribution assembly, having an exhausting buffer for holding the gases passed through the gas exhausting aperture.

### CROSS-REFERENCE TO RELATED APPLICATIONS

This application is based upon and claims the benefit of priority from Japanese Patent Application No. 2014-183916, filed on Sep. 10, 2014.

### TECHNICAL FIELD

The present disclosure provides a substrate processing apparatus, method of manufacturing a semiconductor device, cartridge head, gas distribution assembly and non-transitory computer-readable recording medium thereof.

### BACKGROUND

In the manufacturing process of a semiconductor device, a substrate processing apparatus for forming a film on a substrate is used generally. For example, as a process performed by the substrate processing apparatus, there is a method of supplying gases alternatively for forming a film. In the method of supplying gases alternatively, a process cycle including a step of supplying a source gas, a step of purge, a step of supplying a reactant gas and a step of purge is repeated the predetermined number of times (repeated N cycles) for forming a film on the substrate. As a substrate processing apparatus for performing such a process, there is an apparatus configured to supply the gases (including a source gas, a reactant gas, or a purge gas) to the surface of the substrate from the upper side and configured to exhaust the gases from the surface of the substrate to the upper side.

For example, United States patent application US2011/0212625A1, FIGS. 6 to 11 discloses such a substrate processing apparatus.

To perform a process appropriately by employing the substrate processing apparatus configured to supply gases from the upper side of the substrate and exhaust gases to the upper side, it is necessary to prevent partial deflection of exposure to the gases. However, in the substrate processing apparatus which includes gas supplying ports or gas exhausting ports disposed in circumference respectively and is configured so that the substrate passes under the gas supplying ports or the gas exhausting ports, the width of the gas exhaust port is narrower as the inside of the circumference and wider as the outside of the circumference. Therefore, there is partial deflection of exposure to the gases caused by the differences of the flow resistance between the inside and outside of the substrate processing apparatus. As a result, the film thickness formed on the substrate may not be uniform.

In this disclosure, by preventing partial deflection of exposure to the gases, a substrate processing apparatus, method of manufacturing a semiconductor device and gas distribution assemblies thereof which can process appropriately is provided.

### SUMMARY

According to the present disclosure, there is provided a substrate processing apparatus. The substrate processing apparatus includes a susceptor configured to place a substrate on it, a process gas distribution assembly configured to supply a process gas on a surface of the substrate from the upper side of the susceptor and an inert gas distribution assembly arranged next to the process gas distribution assembly, configured to supply an inert gas on the surface of the substrate from the upper side of the susceptor. The substrate processing apparatus further includes a gas exhausting system, the gas exhausting system has a gas exhausting aperture defined between the process gas distribution assembly and the inert gas distribution assembly, having an exhausting buffer for holding the gases passed through the gas exhausting aperture.

According to another disclosure, there is provided a method of manufacturing a semiconductor device. The method of manufacturing a semiconductor device includes: exposing a substrate placed on a susceptor to a process gas supplied from the upper side of the susceptor by employing a process gas distribution assembly arranged above the susceptor; exposing the substrate to an inert gas supplied from the upper side of the susceptor by employing an inert gas distribution assembly arranged above the susceptor; and exhausting gases upward from the surface of the substrate through a gas exhausting aperture and an exhausting buffer for holding gases passed through the gas exhausting aperture, wherein the gas exhausting aperture is formed between the process gas distribution assembly and the inert gas distribution assembly, corresponding to the susceptor.

Pursuant to another disclosure, there is provided a gas distribution assembly which may be arranged to be opposed to the upper side of the substrate, the gas distribution assembly includes: a gas supplying path configured to supply a gas to the substrate; a first member arranged to surround the upper side of the gas supplying path; and a second member arranged to surround the lower side of the gas supplying path, the plane shape of the second member is wider than that of the first member, wherein the gas distribution assembly configures a part of the gas exhausting aperture defined by the side wall of the second member, configuring a part of the exhausting buffer defined by the side wall of the first member and the upper wall of the wide part of the second member when the gas distribution assembly is arranged at the upper side of a substrate.

Pursuant to the present disclosure, when the gases are supplied from the upper side of the substrate and exhausted to the upper side of the substrate, processing the substrate can perform appropriately by preventing partial deflection of exposure to the gases.

### BRIEF DESCRIPTION OF THE DRAWINGS

FIG. 1 is a conception diagram showing main parts of the substrate processing apparatus according to a first embodiment of the present disclosure.

FIG. 2A is a perspective view of a gas distribution assembly used in the substrate processing apparatus according to a first embodiment of the present disclosure.

FIG. 2B is a side cross-sectional view of the gas distribution assembly used in the substrate processing apparatus according to a first embodiment of the present disclosure.

FIG. 3 is a side cross-sectional view, indicating the A-A section of FIG. 1, showing main parts of the substrate processing apparatus according to a first embodiment of the present disclosure.

FIG. 4 is a side cross-sectional view, indicating the B-B section of FIG. 1, showing main parts of the substrate processing apparatus according to a first embodiment of the present disclosure.

FIG. 5 is a plane cross-sectional view. indicating the C-C section of FIG. 3, showing main parts of the substrate processing apparatus according to a first embodiment of the present disclosure.

FIG. 6 is a plane cross-sectional view. indicating the C-C section of FIG. 3, showing main parts of the substrate processing apparatus according to another embodiment of the present disclosure.

FIG. 7 is a schematic view showing the configuration of gas system and flows of gases according to a first embodiment of the present disclosure.

FIG. 8 is a flowchart showing the steps of processing a substrate according to a first embodiment of the present disclosure.

FIG. 9 is a flowchart showing the step of processing to change the relative position, executed in the steps of forming a film indicating FIG. 8.

FIG. 10 is a flowchart showing the step of processing to supply or exhaust gas, executed in the steps of forming a film indicating FIG. 8.

FIG. 11A is a side view of the gas distribution assembly used in the substrate processing apparatus according to a first embodiment of the present disclosure, showing a pressure balance in an exhausting buffer.

FIG. 11B is a side cross-sectional view of the gas distribution assembly used in the substrate processing apparatus according to a first embodiment of the present disclosure.

FIG. 12A is a perspective view of a gas distribution assembly used in the substrate processing apparatus according to a second embodiment of the present disclosure.

FIG. 12B is a side view of the gas distribution assembly used in the substrate processing apparatus according to the second embodiment of the present disclosure, showing a pressure balance in an exhausting buffer.

FIG. 13A is a perspective view of a gas distribution assembly used in the substrate processing apparatus according to a third embodiment of the present disclosure.

FIG. 13B is a side view of the gas distribution assembly used in the substrate processing apparatus according to the third embodiment of the present disclosure, showing a pressure balance in an exhausting buffer.

FIG. 14 is a side cross-sectional view showing main parts of the substrate processing apparatus according to a fourth embodiment of the present disclosure.

FIG. 15 is a plan cross-sectional view showing main parts of the substrate processing apparatus according to a fourth embodiment of the present disclosure.

FIG. 16 is a plan cross-sectional view showing main parts of the substrate processing apparatus according to another aspect of the fourth embodiment of the present disclosure.

FIG. 17A is a plan cross-sectional view showing main parts of the substrate processing apparatus according to a fifth embodiment of the present disclosure.

FIG. 17B is a plan cross-sectional view showing main parts of the substrate processing apparatus according to another aspect of the fifth embodiment of the present disclosure.

FIG. 18A is a perspective view of a gas distribution assembly used in the substrate processing apparatus according to another embodiment of the present disclosure.

FIG. 18B is a plan D-arrow view of the gas distribution assembly indicated by FIG. 18A.

FIG. 18C is a side E-arrow view of the gas distribution assembly indicated by FIG. 18A.

### DETAILED DESCRIPTION

### The First Embodiment of the Present Disclosure

Hereinafter, the first embodiment of the present disclosure will be described with reference to the drawings.

(1) Configuration of a substrate processing apparatus according to the first embodiment. A substrate processing apparatus according to a first embodiment may be configured to process a plurality of substrates simultaneously. The substrate treated by this substrate processing apparatus may include a semiconductor wafer (hereinafter referred to as “wafer W”) on which a semiconductor integrated circuit device (hereinafter referred to as “semiconductor device”) is formed. Processing to perform for such a substrate may include etching, asking, forming a film. In particular, a method of supplying gases alternatively for forming a film is disclosed.

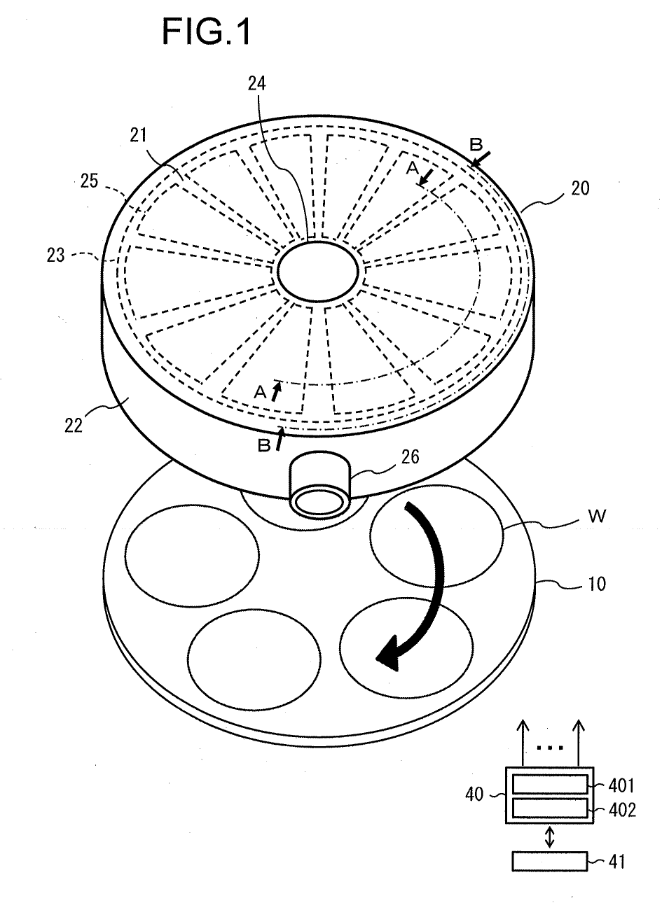

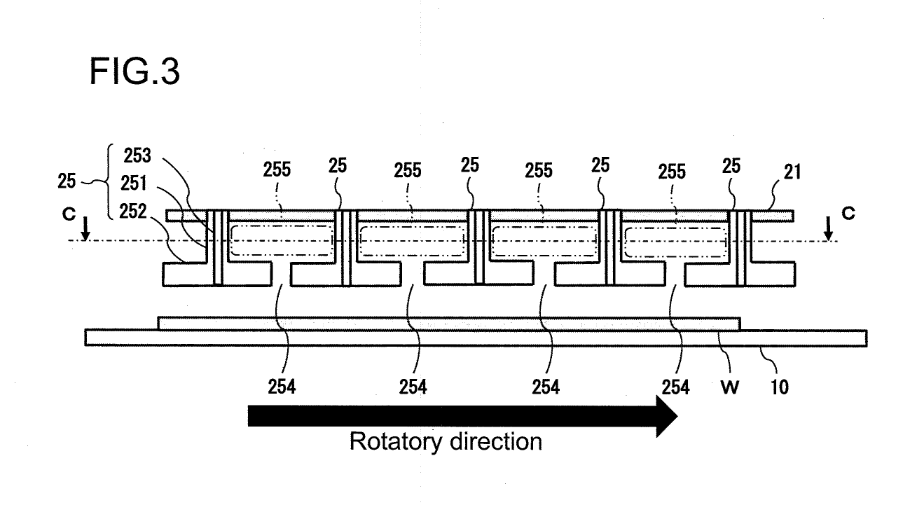

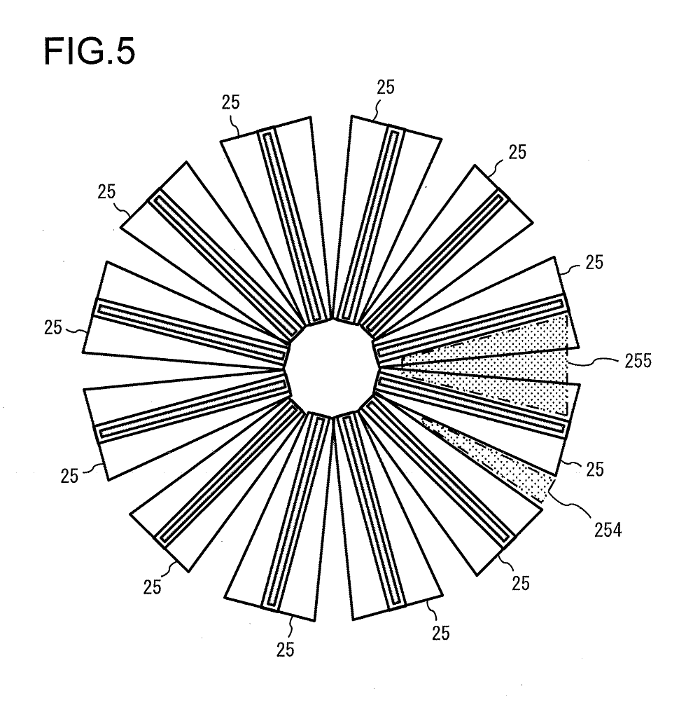

Hereinafter, the configuration of the substrate processing apparatus according to the first embodiment is described with reference to FIG. 1 through FIG. 7.

(Process Chamber)

The substrate processing apparatus according to the first embodiment may include a process chamber which is not illustrated. The process chamber is configured as a closed container made of metallic materials including aluminum (Al) and stainless steel (SUS). Ports to the substrate carry in or out may be disposed in the side wall of the process chamber. The substrate may be transferred through the ports. Additionally, a gas exhausting system including a vacuum pump, a pressure controller etc. not illustrated may be connected to the process chamber. The pressure in the process chamber may be adjustable to the predetermined pressure by employing the gas exhausting system.

(Susceptor)

As shown in FIG. 1, a susceptor 10 on which wafer W can be set may be disposed in the process chamber. Susceptor 10 may be formed like a disk-like shape, being configured so as to set a plurality of substrates at an interval in the circumference direction on the top surface (substrate receiving surface). In addition, the susceptor may include a heater as a heating source, not illustrated. A temperature of wafer W can be maintained at a predetermined temperature by employing the heater. The configuration of setting five wafers W on the susceptor 10 is disclosed in FIG. 1 as an example. The number of wafer W on the susceptor is not limited to this example, it may be decided appropriately. For example, if there are a large number of wafers W on the susceptor, improvement of the processing throughput may be expected, whereas if there are a small number of wafers on it, upsizing of the susceptor may be restrained. It is preferable that the substrate receiving surface on the susceptor 10 may be formed with materials such as quartz or the alumina because the substrate receiving surface may come in contact with wafer W directly.

The susceptor 10 may be configured to be able to rotate under the state which a plurality of substrates are placed on it. Specifically, the susceptor 10 may be rotated around the rotary axis positioned at the center of susceptor 10, by using a rotary driving mechanism, not illustrated. For example, the rotary driving mechanism may include a rotary bearing for supporting the susceptor 10 rotatably, a driving source represented by an electric motor.

Though we disclose the example which susceptor 10 may be configured to be rotatably, if it is possible that the relative position between wafer W on susceptor 10 and cartridge head 20 described later can be moved, it may be possible that cartridge head 20 may be configured to be rotated. If susceptor 10 may be configured to be rotated, complexity of the gas system described later can be restrained in comparison with the case to rotate cartridge head 20. In contrast, the case to rotate cartridge head 20 can restrain the moment of inertia forcing wafer W, so the rotation speed can set faster in comparison with the case to rotate susceptor 10.

(Cartridge Head)

Cartridge head 20 may be disposed at the upper side of susceptor 10 in a process chamber. Cartridge head 20 may work for supplying gases (source gases, reactant gases or purge gases) to wafer W on susceptor 10 from the upper side of it and exhausting supplied gases to the upper side of it.

For supplying gases from the upper side and exhausting gases to the upper side, cartridge head 20 may include ceiling part 21 formed like a disk, outer cylindrical member 22 extended down from outer edge of the ceiling part 21, inner cylindrical member 23 disposed at an inside of the outer cylindrical member 22, center cylindrical member 24 located at the position corresponding to the rotary axis positioned at the center of susceptor 10, a plurality of gas distribution assemblies 25 arranged respectively below ceiling part 21 between inner cylindrical member 23 and center cylindrical member 24. Outer cylindrical member 22 may also include gas exhausting port 26 for communicating with a space defined by the outer cylindrical member 22 and inner cylindrical member 23. Each of ceiling part 21, outer cylindrical member 22, inner cylindrical member 23, center cylindrical member 24, gas distribution assembly 25, gas exhausting port 26 constituting cartridge head 20 may be formed with metallic materials including aluminum (Al) and stainless steel (SUS).

FIG. 1 shows cartridge head 20 where the number of gas distribution assemblies 25 is twelve (12) as an example. The number of gas distribution assemblies 25 contained by cartridge head 20 is not limited to this example, it may be decided appropriately under the consideration regarding the amount of gas which should supply to wafer W, processing throughput, etc. For example, if the process for forming a film may include a cycle step that is composed of a step of supplying a source gas, a step of purge, a step of supplying a reactant gas and a step of purge, described the details later, the number of gas distribution assemblies 25 can make a multiple of four (4) corresponding to the number of each step. To improve the process throughput, it may be preferable that total number of gas distribution assemblies 25 installed in cartridge head 20 is high.

(Gas Distribution Assembly)

Hereinafter, gas distribution assembly 25 in cartridge head 20 is disclosed in detail.

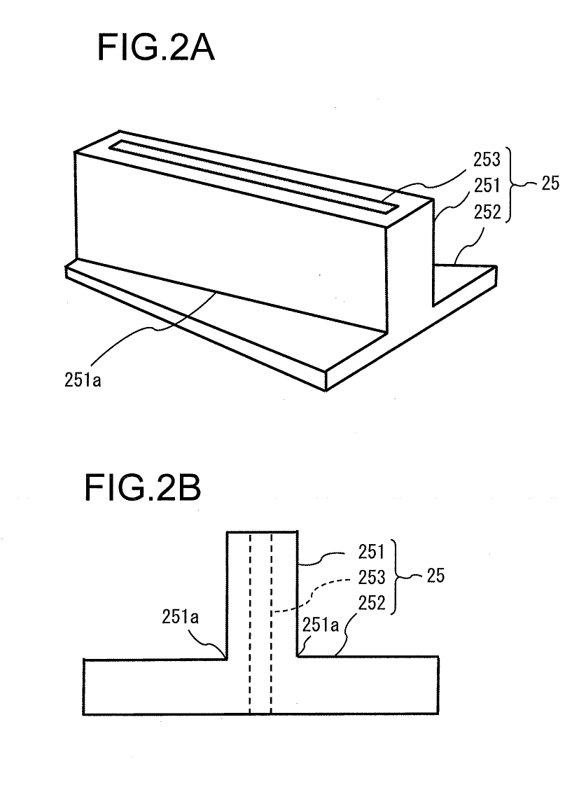

Gas distribution assembly 25 may be configured to form a gas flow path for supplying gases from upper side of wafer W to wafer W and leading exhausting gases to upper side of wafer W. As shown in FIG. 2A, gas distribution assembly 25 may include first member 251 formed into a hollow rectangular solid shape, second member 252 formed into a plate shape having a through-hole communicated with hollow part of first member 251, second member 252 being attached to the bottom of first member 251. The plane shape of second member 252 may be wider than that of first member 251. Specifically, the plane shape of second member 252 may be formed into a fan-shape or trapezoid-shape, where its width in the rotatory direction is gradually increased toward the outside from the side being near to pivot. The degree of the increase in width is not only the case to increase continually but also the case to increase step by step. Having such a first member 251 and second member 252, gas distribution assembly 25 may come to a convex-shape having corners 251a formed by first member 251 and second member 252, looked from the radial direction as shown in FIG. 2B.

Gas distribution assembly 25 may include gas supplying path 253 having a through-hole which plane shape is approximately rectangular as shown in FIG. 2A and FIG. 2B. Gas supplying path 253 may be bored so as to make a through-hole through first member 251 and second member 252. A radial length of the through-hole, in other word, a length in the longitudinal direction of the through-hole may be longer than or equal with the diameter of substrate placed on susceptor 10 so as to supply a gas uniformly to the whole surface of the substrate. Gas supplying path 253 may become a gas flow path for supplying gases to the substrate from the upper side of the principal surface of substrate. In other words, gas distribution assembly 25 may include gas supplying path 253 configured to supply a gas, first member 251 surrounding a upper side of the gas supplying path 253 and second member 252 surrounding a lower side of the gas supplying path 253. Since the width of second member 252 in the rotatory direction is wider than that of first member 251, the gases supplied through gas supplying path 253 can flow horizontally in the domain that was sandwiched between the bottom surface of second member 252 and the corresponding region of susceptor 10, towards gas exhausting aperture 254 explained later. Therefore, the substrate on susceptor 10 can be exposed to the gases more effectively than the case that there is no bottom surface configured by second member 252. By forming the domain between the wide bottom surface of second member 252 and the corresponding region of susceptor 10, the gas adsorption to the substrate can be carried out more effectively. The width of second member 252 in the rotatory direction may be longer than the width of first member 251 in the rotatory direction, but being defined depending on the character of the gas or flow quantity of the gas. To improve an efficiency of gas, the vertical distance formed between the bottom surface of second member 252 and the corresponding region of susceptor 10 may be small enough unless the rotation of the substrates or the horizontal flow of the gas is disturbed. In addition, first member 251 and second member 252 may integrally be formed. In second member 252, the length of the projecting part of right or left respectively extending outwardly from the through-hole in the rotatory direction does not need to be the same length so as to form like a convex-shape. For example, a width of a part of the projecting part which is following the through-hole along the rotatory direction can be longer than a width of a part of the projecting part which is located before than the through-hole along the rotatory direction. In this way, since the gas supplied from the through-hole can flow horizontally during long time in the domain that was sandwiched between the bottom surface of the projecting part of second member 252 and the corresponding region of susceptor 10, the substrate can be exposed to the gas for a long time. In other word, the gas distribution assembly 25 may include first member 251 formed into a hollow rectangular solid shape and second member 252 formed into a fan-shaped or trapezoid-shaped plate having a rectangular through-hole communicated with hollow part of the first member. The length in the longitudinal direction of the through-hole may be longer than or equal with the diameter of a substrate. Second member 252 may have a projecting part extending outwardly from the through-hole in the fan or trapezoidal direction spreading out, the second member being attached to the bottom of first member.

Being configured in this way, a plurality of gas distribution assemblies 25 can be respectively suspended from ceiling part 21 of cartridge head 20, at a prescribed interval. A plurality of gas distribution assemblies 25 may be configured so that each undersurface of second member 252 faces with wafer W on susceptor 10 and the undersurface becomes parallel to wafer W receiving surface on susceptor 10.

According to this arrangement, each gas distribution assembly 25 next to each other may constitute a part of gas exhausting aperture 254 for exhausting gases supplied to wafer W upward, defined by the side wall of the second member 252.

Gas distribution assemblies 25 next to each other may constitute a part of exhausting buffer, partly defined by the side wall of first member 251 and upper wall of the projecting part of second member 252, as a space for holding gases passed through gas exhausting aperture 254. More specifically, the top wall of exhausting buffer 255 may be defined by ceiling part 21. The bottom walls of exhausting buffer 255 may be defined by upper walls of second member 252 in gas distribution member 25 next to each other. The side walls of exhausting buffer 255 may be defined by the side walls of first member 251 next to each other, inner cylindrical member 23 and center cylindrical member 24 of cartridge head 20.

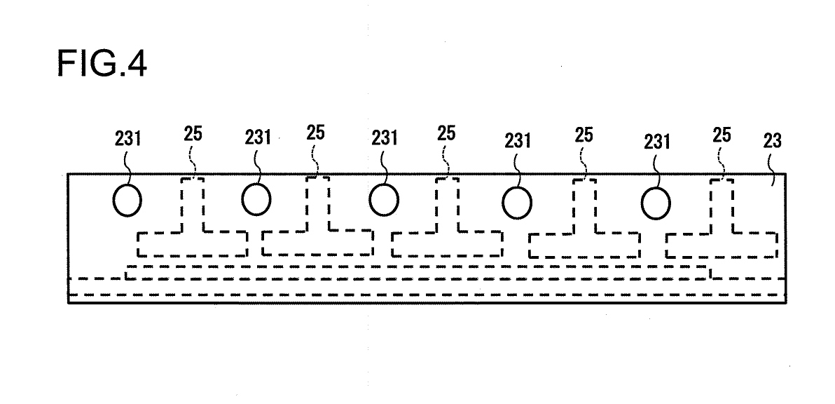

As shown in FIG. 4, exhausting holes 231 may be formed at the wall of inner cylindrical member 23 which defines the side wall of exhausting buffer 255, communicating with the space formed between outer cylindrical member 22 and inner cylindrical member 23. Each exhausting hole 231 may be formed corresponding to exhausting buffer 255 respectively.

Ceiling part 21 of cartridge head 20 may be formed like a disk shape as already described. Therefore, a plurality of gas distribution assemblies 25 suspended from ceiling part may be arranged radially from the pivot side towards an outer side above susceptor 10. In this way, a plurality of gas distribution assemblies 25 may be disposed radially, and disposed along a circumferential direction of susceptor 10.

When a plurality of gas distribution assemblies 25 are arranged radially, since a plane shape of first member 251 in it is rectangular, exhausting buffer 255 which side wall is defined by first member 251 may have the plane shape where its width of the rotatory direction is gradually increased from the inner side being near to pivot side, toward the opposing outer side. Exhausting buffer 255 may be configured so that the width in the rotatory direction is gradually increased from the inner side being near to pivot side, toward the opposing outer side.

Gas distribution assembly 25 may be disposed so that second member 252 having a fan-shaped or trapezoid-shaped bottom wall is spreading for the outside from the pivot side of the susceptor 10. Accordingly, gas exhausting aperture 254 defined by the side wall of second member 252 can have a plane shape spreading for the outside from the pivot side of the susceptor 10.

However, it is not necessary that gas exhausting aperture 254 has the shape that is spreading for the circumference side from the pivot side. As shown in FIG. 6, it may be preferable that gas exhausting aperture 254 is formed like a slit having the same width substantially from the pivot side to the circumference side. As a result of having such a configuration as exhausting aperture 254, an exhaust conductance of each point of the length direction from the pivot side to the circumference side can set almost constantly. Therefore, there is the advantage that it is easy to adjust exhaust efficiency of the gas exhausting system because the exhaust efficiency can be set by only adjusting the structure of exhausting buffer 255, without the consideration regarding the difference of the exhaust conductance of each point of the length direction from the pivot side to the circumference side of exhausting aperture 254.

### (Gas Supplying/Exhausting System)

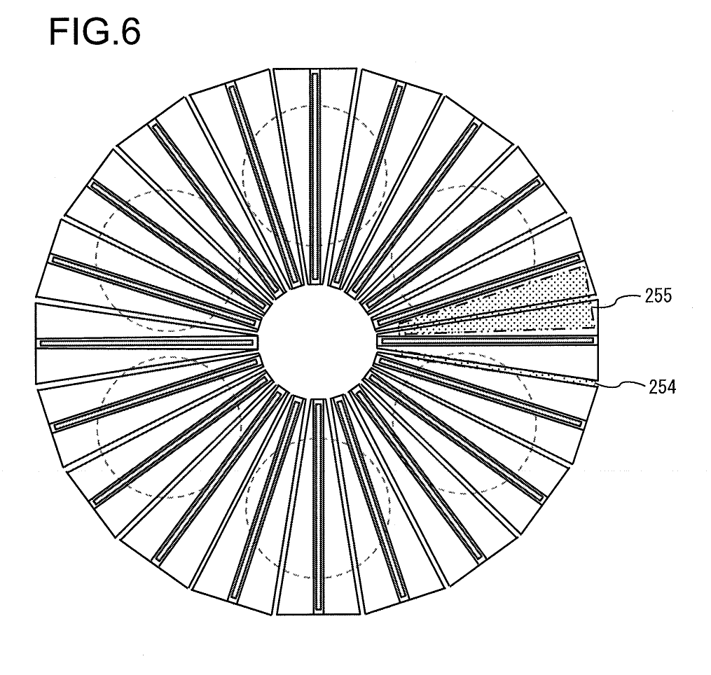

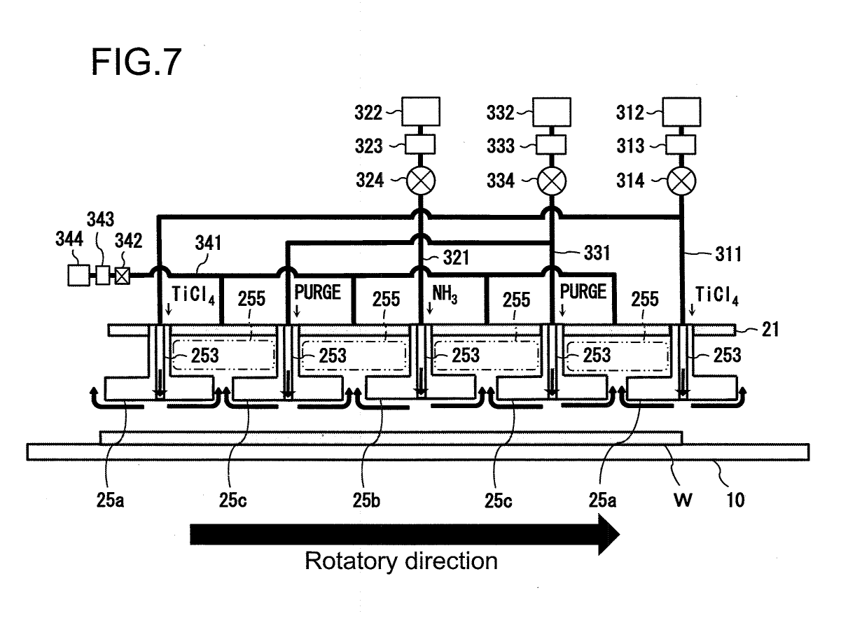

For supplying gases from the upper side of wafer W on susceptor 10 and exhausting gases to the upper side of wafer W on susceptor 10, gas supplying/exhausting system may be connected to gas distribution assembly 25 in the cartridge head 20 as shown in FIG. 7.

(Process Gas Supplying System)

Source gas supplying conduit 311 may be connected to at least one gas supplying path 253 of gas distribution assembly 25a of plural gas distribution assemblies 25 constituting cartridge head 20. Source gas supplying conduit 311 may connect source of source gas 312, mass flow controller (MFC) 313 for controlling the quantity of gas flow and valve 314 for coordinating an opening and shutting degree, sequentially from the upper sides. According to this arrangement, gas supplying path 253 of gas distribution assembly 25a where source gas supplying conduit 311 is connected to, can deliver a source gas to the surface of wafer W on susceptor 10 from upper side. Hereinafter, this gas distribution assembly 25a connected to gas supplying conduit 311 may be called as “source gas distribution assembly”. In other words, source gas distribution assembly 25a may be located at the upper side of susceptor 10, to deliver the source gas to the surface of wafer W on susceptor 10 from upper side.

The source gas is one of the processing gas for supplying to wafer W, vaporized titanium tetrachloride (TiCl4) which is a metal liquid raw materials including the titanium (Ti) element. The source gas may be solid, liquid or gas under the room temperature and ordinary pressure. In the case that the precursor is liquid under the room temperature and ordinary pressure, the vaporizer (not illustrated) should be disposed between source of source gas 312 and MFC 313. In this disclosure, the precursor may be gas under the room temperature and ordinary pressure.

In addition, a gas supplying system, not illustrated, for delivering an inert gas as a carrier gas may be connected to source gas supplying conduit 311. For example, the inert gas acting as carrier gas can use nitrogen (N2) gas specifically. In addition, the rare gas such as helium (He) gas, neon (Ne) gas, argon (Ar) gas may be used other than nitrogen (N2) gas.

The other gas distribution assembly 25b may be disposed at the position across gas distribution assembly 25c next to gas distribution assembly 25a connected to source gas supplying conduit 311. Gas distribution assembly 25b may be connected to gas supplying path 253 of reactant gas supplying conduit 321. Reactant gas supplying conduit 321 may connect source of reactant gas 322, mass flow controller (MFC) 323 for controlling the quantity of gas flow and valve 324 for coordinating an opening and shutting degree, sequentially from the upper sides. According to this arrangement, gas supplying path 253 of gas distribution assembly 25b where reactant gas supplying conduit 321 is connected to, can deliver a reactant gas to the surface of wafer W on susceptor 10 from upper side. In other words, reactant gas distribution assembly 25b may be located at the upper side of susceptor 10, deliver the reactant gas to the surface of wafer W on susceptor 10 from upper side.

In this disclosure, “source gas distribution assembly” and “reactant gas distribution assembly” may be called as “process gas distribution assembly” generally. In addition, one of “source gas distribution assembly” or “reactant gas distribution assembly” may be called as “process gas distribution assembly”.

The reactant gas is one of the process gas for supplying to wafer W. For example, ammonia (NH3) gas may be used.

In addition, a gas supplying system, not illustrated, for delivering an inert gas acting as a carrier gas or a dilution gas of reactant gas may be connected to reactant gas supplying conduit 321. For example, the inert gas acting as a carrier gas or a dilution gas can use nitrogen (N2) gas specifically. In addition, the rare gas such as helium (He) gas, neon (Ne) gas, argon (Ar) gas may be used other than nitrogen (N2) gas.

In addition, a matching device and a radio frequency power supply, not illustrated, may be coupled to gas distribution assembly 25b. By adjusting impedance by the matching device and the radio frequency power supply, the plasma may be generated under space of gas distribution assembly 25b.

Mainly, process gas supplying system may include source gas supplying conduit 311, source of source gas 312, MFC 313, valve 314, gas supplying path 253 of gas distribution assembly 25a where source gas supplying conduit 311 is connected to, reactant gas supplying conduit 321, source of reactant gas 322, MFC 323, valve 324 and gas supplying path 253 of gas distribution assembly 25b where reactant gas supplying conduit 321 is connected to.

(Inert Gas Supplying System)

Gas distribution assembly 25c may be disposed at the position between gas distribution assembly 25a which is connected to source gas supplying conduit 311 and gas distribution assembly 25b which is connected to reactant gas supplying conduit 321. Inert gas supplying conduit 331 may be connected to gas supplying path 253 which may be included in gas distribution assembly 25c. Inert gas supplying conduit 331 may connect source of inert gas 332, mass flow controller (MFC) 333 for controlling the quantity of gas flow and valve 334 for coordinating an opening and shutting degree, sequentially from the upper sides. According to this arrangement, gas supplying path 253 of gas distribution assembly 25c connected to inert gas supplying conduit 331, can deliver an inert gas to the surface of wafer W on susceptor 10 from upper side, at the position next to gas distribution assembly 25a which is connected to source gas supplying conduit 311 and gas distribution assembly 25b which is connected to reactant gas supplying conduit 321. This gas distribution assembly 25c, connected to inert gas supplying conduit 331, may be called as “inert gas distribution assembly”.
In other words, inert gas distribution assembly 25c may be located at the position next to source gas distribution assembly 25a or reactant gas distribution assembly 25b, delivering the reactant gas to the surface of wafer W on susceptor 10 from upper side.

The inert gas may act as an air seal sealing the space defined between top surface of wafer W and undersurface of gas distribution assembly 25c so that a source gas is not mixed with a reactant gas in the top surface of wafer W. For example, nitrogen (N2) gas may be used as the inert gas. In addition, the rare gas such as helium (He) gas, neon (Ne) gas, argon (Ar) gas may be used other than nitrogen (N2) gas.

Inert gas supplying system may include inert gas supplying conduit 331, source of inert gas 332, MFC 333, valve 334 and gas supplying path 253 which may be included in gas distribution assembly 25c connected to inert gas supplying conduit 331.

(Gas Exhausting System)

Gas exhausting port 26 disposed in cartridge head 20 may be connected to gas exhausting conduit 341. Gas exhausting conduit 341 may include valve 342. Additionally, pressure controller 343 for controlling the pressure of inside space of outer cylindrical member 22 in cartridge head 20, to predetermined pressure value, may be disposed in the downstream of valve 342. Furthermore, vacuum pump 344 may be disposed at the downstream of pressure controller 343 in gas exhausting conduit 341.

According to such a configuration, the evacuation may be performed through gas exhausting port 26 in cartridge head 20, from the inside space of outer cylindrical member 22. As exhausting holes 231 are disposed in the wall of inner cylindrical member 23, inside of inner cylindrical member (in other words, exhausting buffer 255) may be communicated into outside of it (in other words, the space formed between outer cylindrical member 22 and inner cylindrical member 23). Therefore, when the evacuation is performed through gas exhausting port 26, a flow of the gas toward exhausting holes 231 may occur in exhausting buffer 255 and a flow of the gas from gas exhausting aperture 254 toward exhausting buffer 255 (in other words, a flow of the gas from gas exhausting aperture 254 toward upper side). In this way, the gases on wafer W, supplied from the process gas supplying system or inert gas supplying system, in other words, a source gas, a reactant gas or an inert gas may be exhausted toward the upper side of wafer W through exhausting buffer 255, from gas exhausting aperture 254 formed between gas distribution assemblies 25. Furthermore, the gases in exhausting buffer 255 may be exhausted outside of cartridge head 20 through exhausting holes 231 and gas exhausting port 26.

Gas exhausting system may include gas exhausting aperture 254 formed between gas distribution assemblies 25, exhausting buffer 255, exhausting holes 231, gas exhausting port 26, gas exhausting conduit 341, valve 342, pressure controller 343 and vacuum pump 344. In other word, the gas exhausting system may include the gas exhausting aperture 254 defined between the process gas distribution assembly and the inert gas distribution assembly, the gas exhausting system may also include an exhausting buffer, partly defined by the upper walls of the projecting parts and side walls of the gas distribution assemblies next to each other, wherein the gas exhausting system may be configured to exhaust a gas being in the domain sandwiched between the bottom surface of projecting part and the corresponding region of susceptor 10, through the exhausting buffer 255 via the gas exhausting aperture 254.

(Controller)

As shown in FIG. 1, the substrate processing apparatus according to a first embodiment of the present disclosure may have controller 40 controlling the operation of each part of the substrate processing apparatus. Controller 40 may have at least arithmetic logical member 401 and memory member 402. Controller 40 can be connected with each element mentioned above. According to the indication of the further host controller or an operator, controller 40 can load specified programs or recipes from memory member 402 to execution memory and control the operation of each element. Specifically, controller 40 may control the rotary driving mechanism, the heater, the radio frequency power supply, the matching device, MFC 313-333, valve 314-334, 342, pressure controller 343 and vacuum pump 344.

In addition, controller 40 may constitute it as an exclusive computer and may constitute it as a general-purpose computer. In one embodiment, controller 40 can be constituted by a general-purpose computer which includes external memory 41 installing above mentioned program. As external memory 41, there can be a magnetic tape, a magnetic disk such as a flexible disc or a hard disk, optical disk such as a CD or a DVD, a magneto-optical disk such as an MO or a semiconductor memory included in such as a USB memory (USB Flash Drive) or the memory card etc.

The means to install the program to a computer are not limited to the means supplying it through the external memory. For example, installing the program by using the means of communications such as the Internet or the exclusive line, without external memory 41, can be possible. In addition, memory member 402 or external memory 41 are comprised as the recording medium that computer reading is possible. Hereinafter, recording medium means these memories collectively. When the terminology recording medium is used hereinafter in this specification, the terminology is defined as just the memory member 402, external memory 41 or both of memory member 401 and external memory 41.

(2) Substrate Processing Process

Next, by employing the substrate processing apparatus according to the first embodiment, the process forming a film on wafer W is explained as a method of manufacturing a semiconductor device. The operations of the parts constituting the substrate processing apparatus may be controlled by controller 40.

By supplying titanium tetrachloride (TiCl4) gas vaporized titanium tetrachloride (TiCl4) as a source gas (a first process gas) and ammonia (NH3) gas as a reactant gas (a second process gas) alternatively, an example of forming titanium nitride (TiN) film as a metal film on wafer W is explained.

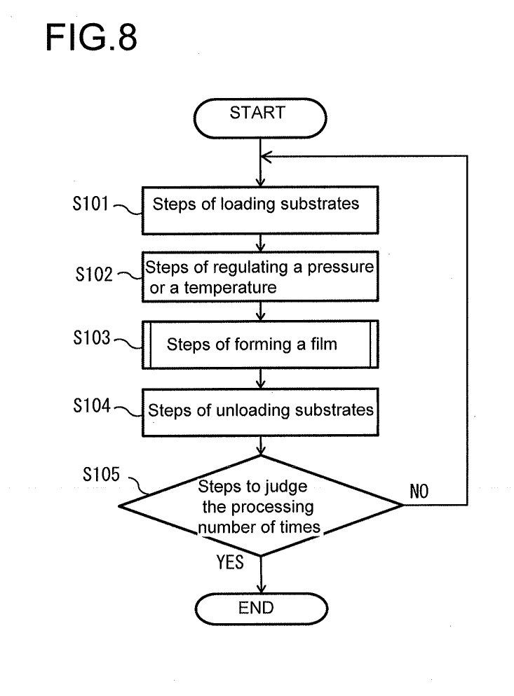

Basic operations in the substrate processing process Firstly, basic operations in the substrate processing process for forming a film on wafer W are explained. FIG. 8 is a flowchart showing the steps of processing a substrate according to a first embodiment of the present disclosure.

(Steps of Loading Substrates: S101)

At first, as steps of loading substrates (S101) in the substrate processing apparatus according to the first embodiment, a port for import or export of the substrate may be opened, thereby a plurality of wafers W (for example, five (5) pieces of wafers W) may be imported into the process chamber by using a conveyance device (not shown) and may be planarly placed on susceptor 10. Then, the conveyance device may be evacuated to the outside of the process chamber, thereby the process chamber may be sealed by closing the port for import or export of the substrate.

(Steps of Regulating a Pressure or a Temperature: S102)

After the steps of loading substrates (S101), steps of regulating a pressure or a temperature (S102) may be executed. In the steps of regulating a pressure or a temperature (S102), after the process chamber was sealed in the steps of loading substrate (S101), the pressure in the process chamber may be controlled so as to become predetermined pressure by employing the gas exhausting system (not shown) connected to the process chamber. The predetermined pressure is the processing pressure that can form a titanium nitride (TiN) film in the steps of forming a film (S103) to mention later. For example, the predetermined pressure may be the pressure that the source gas may not decompose itself. Specifically, the processing pressure may be from 50 Pa to 5,000 Pa. This processing pressure may be maintained in the steps of forming a film (S103) to mention later.

In addition, the temperature at the surface of wafer W may be controlled so as to become a predetermined temperature by supplying the electric power to the heater embedded in susceptor 10. In this case, the temperature of the heater may be regulated by controlling the electricity condition to the heater based on temperature information detected by a temperature sensor which is not illustrated. The predetermined temperature is the processing temperature that can form a titanium nitride (TiN) film in the steps of forming a film (S103) to mention later. For example, the predetermined temperature may be the temperature that the source gas may not decomposition itself. Specifically, the processing temperature may be more than room temperature and less than 500 degrees Celsius, preferably more than room temperature and less than 400 degrees Celsius. This processing temperature may be maintained in the steps of forming a film (S103) to mention later.

(Steps of Forming a Film: S103)

After the steps of regulating a pressure or a temperature (S102), steps of forming a film (S103) may be executed. Processing to change the relative position and processing to supply or exhaust gas may be included in the processes performed in the steps of forming a film (S103). Processing to change the relative position and processing to supply or exhaust gas will be detailed later.

(Steps of Unloading Substrates: S104)

After the steps of forming a film (S103), steps of unloading substrates (S104) may be executed. In the steps of unloading substrates, the wafers W which have processed may be exported to the outside of the process chamber by using the conveyance device, in the procedure that is reverse of the steps of loading substrates (S101) already explained.

(Steps to Judge the Processing Number of Times: S105)

After exporting wafers W, controller 40 may judge whether the enforcement number of times of each steps including steps of loading substrates (S101), steps of regulating a pressure or a temperature (S102), steps of forming a film (S103) and steps of unloading substrates (S104) may reach the predetermined number of times (S105). In the case that the enforcement number of times of each step has not reached the predetermined number of times yet, controller 40 may shift the control to steps of loading substrate (S101) for starting handling of wafer W waiting next. In the case that the enforcement number of times of each step has reached the predetermined number of times, controller 40 may finish each a series of processes after having performed a cleaning process for the process chamber as needed. The explanation regarding the cleaning process is omitted because the cleaning process can be performed by using a well-known technique.

(Processing to Change the Relative Position)

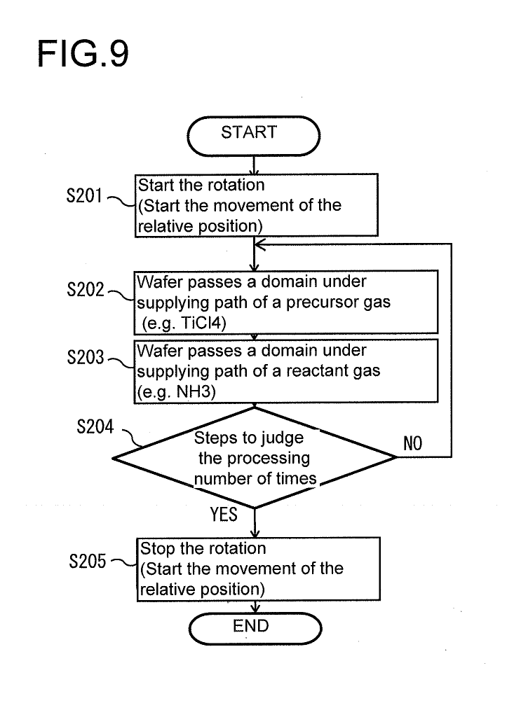

Next, the processing to change the relative position in the steps of forming a film (S103) is explained. The processing to change the relative position means that the relative position with each wafer W on susceptor 10 and cartridge head 20 is changed by rotating susceptor 10. FIG. 9 is a flowchart showing the step of processing to change the relative position, executed in the steps of forming a film indicating FIG. 8.

In the processing to change the relative position in the steps of forming a film (S103), firstly, the movement of the relative position of susceptor 10 and cartridge head 20 may be started under rotating susceptor 10 by using the rotary driving mechanism (S201). In this way, each wafer W placed on susceptor 10 may path the domain under each gas distribution assembly 25 constituting cartridge head 20 sequentially.

Then, processing to supply or exhaust gas detailed later may start in cartridge head 20. In this way, a source gas (e.g. titanium tetrachloride (TiCl4) gas) may be supplied from gas supplying path 253 in some gas distribution assembly 25a, and a reactant gas (e.g. ammonia (NH3) gas) may be supplied from gas supplying path 253 in other gas distribution assembly 25b which sandwiched gas distribution assembly 25c between gas distribution assembly 25a. Hereinafter, the process gas supplying system including gas supplying path 253 for delivering a source gas is called as “a source gas supplying system” and the process gas supplying system including gas supplying path 253 for delivering a reactant gas is called as “a reactant gas supplying system”.

Here, when paying attention to a certain one wafer W, when susceptor 10 starts turning, wafer W may pass a domain under gas supplying path 253 in a source gas supplying system (S202). Then, a source gas (e.g. titanium tetrachloride (TiCl4) gas) may be supplied to the surface of wafer W from gas supplying path 253. Supplied gas may be adhered to wafer W, then a layer including a precursor may be formed. The time when wafer W passes over the domain under gas supplying path 253 in a source gas supplying system, in other words, the supplying time for a source gas, may be adjusted so that it becomes 0.1 to 20 seconds.

After passing over the domain under gas supplying path 253 in a source gas supplying system, wafer W may pass a domain under gas supplying path 253 in an inert gas supplying system. Next, wafer W may pass a domain under gas supplying path 253 in a reactant gas supplying system (S203). Then, a reactant gas (e.g. ammonia (NH3) gas) may be supplied to the surface of wafer W from gas supplying path 253. In addition, the plasma may be generated in the domain under the reactant gas supplying system by employing a matching device and a radio frequency power supply, not illustrated. A plasma activated reactant gas may be delivered on wafer W uniformly. The plasma activated reactant gas may react with the reactants which may be adsorbing on the surface of wafer W or may be containing in the layer formed on wafer W, then a titanium nitride (TiN) film may be formed on wafer W. The time when wafer W passes over the domain under gas supplying path 253 in a reactant gas supplying system, in other words, the supplying time for a reactant gas, may be adjusted so that it becomes 0.1 to 20 seconds.

The movement that wafer W passes under gas supplying path 253 in the source gas supplying system and the movement that wafer W passes under gas supplying path 253 in the reactant gas supplying system, which are disclosed above, as one (1) cycle, Controller 40 judges whether the predetermined number of times (n cycle) enforced this cycle (S204). When this cycle is enforced the predetermined number of times, the titanium nitride (TiN) film having a desired thickness may be formed on wafer W. In other words, in the steps of forming a film (S103), by changing the relative position of wafer W and gas supplying path in the precursor or reactant gas supplying system respectively, cyclic processes to repeat a process which supplies different processing gas alternatively may be performed. As these cyclic processes may be performed to each wafer W on susceptor 10 respectively, a titanium nitride (TiN) film may be formed on wafer W concurrently in the steps of forming a film (S103).

When controller 40 detects that these cycle processes have performed the predetermined number of times, controller 40 may stop the rotation of susceptor 10, then stop the processing to change the relative position of susceptor 10 and cartridge head 20 (S205). In this way, the processing to change the relative position is terminated. When the cycle processes are performed predetermined number of times, the processing to supply or exhaust gas also be terminated.

(Processing to Supply or Exhaust Gas)

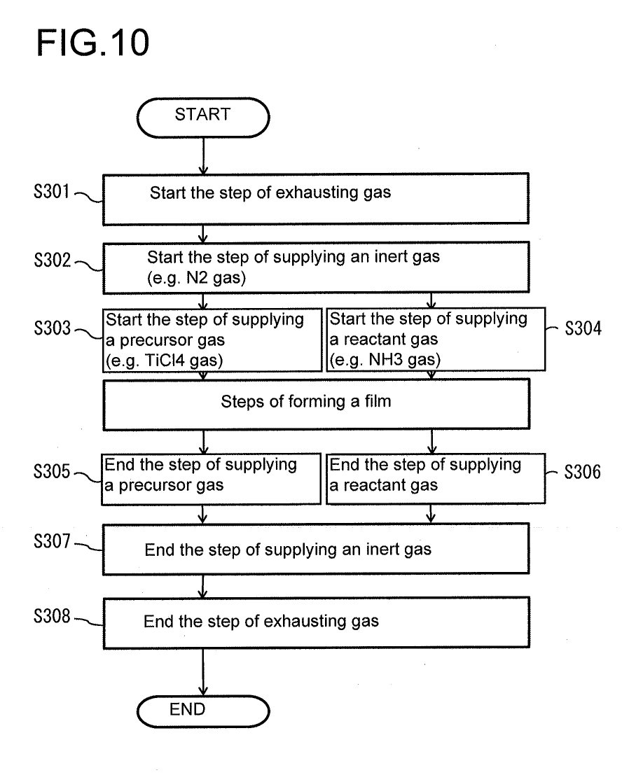

Next, processing to supply or exhaust gas in the steps of forming a film (S103) is disclosed. The processing to supply or exhaust gases includes supplying gases from the upper side of wafer W on susceptor 10 and exhausting gases to the upper side of wafer W on susceptor 10. FIG. 10 is a flowchart showing the step of processing to supply or exhaust gas, executed in the step of forming a film indicating FIG. 8.

At first, step of exhausting gas (S301) is started in the steps of forming a film (S103). In the step of exhausting gas (S301), valve 342 may be kept open under operating vacuum pump 344. Then, pressure controller 343 may control the pressure of the lower space of gas exhausting aperture 254 formed between gas distribution assemblies 25 to the predetermined pressure. The predetermined pressure is lower than the pressure of the lower space of gas exhausting aperture 254 formed between gas distribution assemblies 25. In the way, in the step of exhausting gas (S301), the gases existing in the lower space of gas distribution assembly 25 may be exhausted to the outside of cartridge head 20, through gas exhausting aperture 254, exhausting buffer 255, exhausting holes 231, the space formed between outer cylindrical member 22 and inner cylindrical member 23 and gas exhausting port 26.

After starting the step of exhausting gas (S301), the step of supplying an inert gas (S302) may start successively. In the step of supplying an inert gas (S302), valve 334 disposed in inert gas supplying conduit 331 may be kept open and MFC 333 may be controlled so that flow rate of the inert gas becomes the predetermined flow rate. Then, the inert gas (N2 gas) may be supplied to the surface of wafer W from the upper side of susceptor 10, through gas supplying path 253 in gas distribution assembly 25c connected inert gas supplying conduit 331. For example, the flow quantity of the inert gas is 100-10,000 sccm.

In this step of supplying an inert gas (S302), the inert gas (N2 gas) injected from gas supplying path 253 in gas distribution assembly 25c may spread through the space between the undersurface of second member 252 and top surface of wafer W because the undersurface of second member 252 is parallel to wafer W. As the step of exhausting gas (S301) has already started, the inert gas (N2 gas) spreading through the space between the undersurface of second member 252 and top surface of wafer W may be exhausted from gas exhausting aperture 254 toward the upper side of wafer W. In this way, an air curtain by the inert gas is formed at the lower space of gas distribution assembly 25c connected to inert gas supplying conduit 331.

After starting the step of supplying an inert gas (S302), starting the step of supplying a source gas (S303) and starting the step of supplying a reactant gas (S304) may be executed.

On the occasion of the step of supplying a source gas (S303), the source gas (i.e. titanium tetrachloride (TiCl4) gas) may have been generated by vaporizing source materials (i.e. titanium tetrachloride (TiCl4) which are in a liquid state (preliminary vaporization). As generating a source gas stably need some time, the preliminary vaporization of source materials may run side by side with the steps of loading substrate (S101) or the steps of regulating a pressure or a temperature (S102) already disclosed.

After starting generation of a source gas, in the step of supplying a source gas (S303), valve 314 disposed in source gas supplying conduit 311 may be kept open and MFC 313 may be controlled so that flow rate of the source gas becomes the predetermined flow rate. Then, the source gas (titanium tetrachloride (TiCl4) gas) may be supplied to the surface of wafer W from the upper side of susceptor 10, through gas supplying path 253 in gas distribution assembly 25a connected to inert gas supplying conduit 311. For example, the flow quantity of the source gas may be 10-3,000 sccm.

In this case, as carrier gas of the source gas, an inert gas (N2 gas) may be supplied. For example, the flow quantity of the inert gas may be 10-5,000 sccm.

In this step of supplying a source gas (S303), the source gas (TiCl4 gas) injected from gas supplying path 253 in gas distribution assembly 25a may spread through the space between the undersurface of second member 252 and top surface of wafer W because the undersurface of second member 252 is parallel to wafer W. As the step of exhausting gas (S301) has already started, the source gas (TiCl4 gas) spreading through the space between the undersurface of second member 252 and top surface of wafer W may be exhausted from gas exhausting aperture 254 toward the upper side of wafer W. As the air curtain by the inert gas has already formed at the lower space of gas distribution assembly 25c by starting the step of supplying an inert gas (S302), the source gas spreading through the space under gas distribution assembly 25a may not flow into the space under gas distribution assembly 25c adjacent to gas distribution assembly 25c.

In addition, in the step of supplying a reactant gas (S304), valve 324 disposed in reactant gas supplying conduit 321 may be kept open and MFC 323 may be controlled so that flow rate of the reactant gas becomes the predetermined flow rate. Then, the reactant gas (ammonia (NH3) gas) may be supplied to the surface of wafer W from the upper side of susceptor 10, through gas supplying path 253 in gas distribution assembly 25b connected to reactant gas supplying conduit 321. For example, the flow quantity of the reactant gas may be 10-10,000 sccm.

In this case, as carrier gas or dilution gas of the reactant gas, an inert gas (N2 gas) may be supplied. For example, the flow quantity of the inert gas may be 10-5,000 sccm.

In this step of supplying a reactant gas (S304), the reactant gas (NH3 gas) injected from gas supplying path 253 in gas distribution assembly 25b may spread through the space between the undersurface of second member 252 and top surface of wafer W because the undersurface of second member 252 is parallel to wafer W. As the step of exhausting gas (S301) has already started, the reactant gas (NH3 gas) spreading through the space between the undersurface of second member 252 and top surface of wafer W may be exhausted from gas exhausting aperture 254 toward the upper side of wafer W. As the air curtain by the inert gas has already formed at the lower space of gas distribution assembly 25c by starting the step of supplying an inert gas (S302), the reactant gas spreading through the space under gas distribution assembly 25b may not flow into the space under gas distribution assembly 25c adjacent to gas distribution assembly 25c.

Each step disclosed above (S301-S304) may perform concurrently during the steps of forming a film (S103). To improve inert gas shielding property, the start timing of these each step may be preferable to arrange in a sequence that disclosed above, but not limited to this sequence, each step (S301-S304) can start concurrently.

By performing each step (S301-S304) concurrently, each wafer W placed on susceptor 10 may pass through the lower space of gas distribution assembly 25a for supplying a source gas (TiCl4 gas), then through the lower space of gas distribution assembly 25b for supplying a reactant gas (NH3) sequentially. Moreover, gas distribution assembly 25c for supplying an inert gas (N2 gas) may be arranged between gas distribution assembly 25a for supplying a source gas and gas distribution assembly 25b for supplying a reactant gas, the source gas for supplying to each wafer W may not mix with the reactant gas.

On the occasion of the end of processing to supply or exhaust gas, ending the step of supplying a source gas (S305) and ending the step of supplying a reactant gas (S306) may be executed, then ending the step of supplying an inert gas (S307) and ending the step of exhausting gas (S308) may be executed. The end timing of these each step (S305-S308) may be preferable to arrange in a sequence that disclosed above, but not limited to this sequence, each step (S305-S308) can execute concurrently.

(Gas Flows in the Processing to Supply or Exhaust Gas)

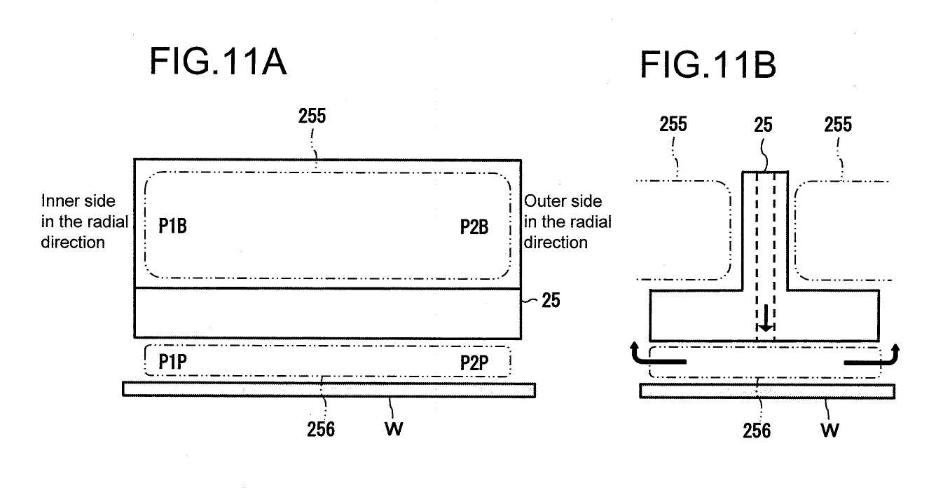

Hereinafter, the gas flows under the state of performing each step (S301-S304) concurrently, especially gas flows toward upper side of wafer W, through gas exhausting aperture 254, is disclosed in detail. FIG. 11A is a side view of the gas distribution assembly 25 used in the substrate processing apparatus according to a first embodiment of the present disclosure, showing a pressure balance in an exhausting buffer. FIG. 11B is a side cross-sectional view of the gas distribution assembly 25 used in the substrate processing apparatus according to a first embodiment of the present disclosure.

In the step of supplying a source gas (S303) and the step of supplying a reactant gas (S304), each gas (a source gas or a reactant gas) may be supplied to wafer W on susceptor 10 and gases supplied to wafer W may be exhausted through gas exhausting aperture 254 toward the upper side of wafer W.

Then, the pressures in the space 256, defined between the undersurface of second member 252 in gas distribution assembly 25 and top surface of wafer W, is defined “P1P” as a pressure of inner side and “P2P” as a pressure of outer side when susceptor 10 rotates. The pressures in exhausting buffer 255 is also defined “P1B” as a pressure of inner side and “P2B” as a pressure of outer side when susceptor 10 rotates.

If the pressures in the space 256, defined between the undersurface of second member 252 in gas distribution assembly 25 and top surface of wafer W, is equal at the radial direction (P1P=P2P), the exposure of a precursor or a reactant gas to wafer W may be uniform at the radial direction of susceptor 10. Then, a titanium nitride (TiN) film formed on wafer W may have a good film thickness distribution by reducing film thickness deviations.

If each gas distribution assembly 25 constituting cartridge head 20 was arranged to spread mainly on an axis of susceptor 10 radially, the width of the circumference direction of gas exhausting aperture 254 formed between gas distribution assemblies 25 might become narrow as the inner side and wide as the outer side of the radial direction of gas exhausting aperture 254. Therefore, in exhausting gases through gas exhaust aperture 254, the flow resistance of inner side of the radial direction of gas exhaust aperture 254 might become higher than that of outer side of gas exhausting aperture 254. In other words, caused by a difference of the flow resistance of inner side and outer side of the radial direction of gas exhaust aperture 254, the pressure of inner side (P1P) might become higher than that of outer side (P2P). Then, deflection of exposure to gases between inner side and outer side of wafer W might occur. As a result, the film thickness formed on wafer W might not become uniform.

However, in the substrate processing apparatus according to a first embodiment of the present disclosure, when the gases supplied to wafer W are exhausted to upper side of wafer W, the gases passed through gas exhausting aperture 254 may flow into exhausting buffer 255 and spread in exhausting buffer 255. In other words, the gases supplied to wafer W may pass through gas exhausting aperture 254 and exhausting buffer 255, then the gases may be exhausted after an accumulation in exhausting buffer 255.

By disposing such exhausting buffer 255, as the gases which should be exhausted may be accumulated temporarily in exhausting buffer 255, the difference between the pressure of inner side of exhausting buffer 255 (P1B) and the pressure of outer side of exhausting buffer 255 (P2B) can lower. Therefore, in the space 256 under gas distribution assembly 25, the difference between the pressure of inner side (P1P) and the pressure of outer side (P2P) can also lower. As a result, deflection of exposure to gases between inner side and outer side of wafer W can be restrained. Then, the surface of wafer W may be processed uniformly.

More specifically, the flow of the gas toward exhausting buffer 255 from gas exhausting aperture 254 may be determined by ΔP1 (=P1P−P1B) or ΔP2 (=P2P−P2B). By disposing exhausting buffer 255, since the difference in pressure with P1P and P2B may become lower than the difference in pressure with P1P and P2B in the state that there is no exhausting buffer 255, then, ΔP1 almost equals ΔP2. Therefore, P1P may become almost equal to P2B. When P1P becomes almost equal to P2B, the distribution of the film thickness of the titanium nitride (TiN) film formed on wafer W may become good because the deviations of film thickness may be suppressed.

In addition, when exhausting buffer 255 is disposed, exhaust efficiency from gas exhausting aperture 254 may be raised in comparison with a case not to be disposed exhausting buffer 255. Therefore, the byproducts such as reaction inhibition things (e.g., ammonia chloride) generated in the space 256 located under gas distribution assembly 25 can be exhausted effectively. When there is no exhausting buffer 255, reaction inhibition things may be deposited on wafer W again in an exhausting process. Then, a reaction on wafer W may be in inhibited and a film thickness on wafer W may become thin. Whereas, when exhausting buffer 255 is disposed, reaction inhibition things may be exhausted effectively, the deposition of the byproducts such as reaction inhibition things can be suppressed. In addition, when exhausting buffer 255 is disposed, because the film which was formed on the wall of exhausting buffer 255 unexpectedly and came off the wall of exhausting buffer 255 may fall into the top surface of the wide part of second member 252, such films may not spread on the surface of wafer W.

### (3) Effect in the First Embodiment

For example, one or more effects in the first embodiment are shown below.

(a) According to the first embodiment, as exhausting buffer 255 is disposed at the cartridge head 20, when the widths of gas exhausting aperture 254 are not uniform, the pressure difference between P1P and P2P at the space under gas distribution assembly 25 can be lower by refraining a difference of the flow resistance under exhausting gases toward upper side through gas exhausting aperture 254. Therefore, deflection of exposure to gases on wafer W can be refrained and uniformity of the surface of wafer W may be improved. In other words, in the processing to supply gases from the upper side of wafer W and to exhaust gases to the upper side of wafer W, forming a film on wafer W can be performed appropriately under the restraint of the partial deflection of exposure to gases on wafer W.

(b) According to the first embodiment, as susceptor 10 may be configured to be rotated under the state that a plurality of wafers W are placed on it, furthermore, the undersurface of each gas distribution assembly 25 which configures the process gas supplying system or inert gas supplying system is formed like a fan-shape or trapezoid-shape which is spreading for the outside from the pivot side of the susceptor 10. The rotary driving mechanism, not illustrated, may rotate susceptor 10 so as to move the relative position between susceptor 10 and gas distribution assembly 25 to rotatory direction. Therefore, mechanism of the configuration for moving the relative position can be simplified in comparison with the configuration for moving the relative position linearly and productivity of the forming films can be raised by processing a plurality of wafers W concurrently. In addition, as the undersurface of each gas distribution assembly 25 is formed like a fan-shape or trapezoid-shape, gas distribution assemblies 25 may be arranged on the circumference. Then, high-pressure gas can be supplied efficiently on susceptor 10. The deflection of exposure to gases between inner side and outer side of wafer W is restrained, then the surface of wafer W may be processed uniformly.

(c) According to the first embodiment, forming a film on wafer W is performed under the condition that move the relative position between wafer W placed on susceptor 10 and gas distribution assembly 25 which configures the process gas supplying system or inert gas supplying system. Therefore, the consumption of the process gases (source gases or reactant gases) can be reduced in comparison with the consumption of gases caused by the method that includes the step of filling the process chamber with a precursor or reactant gas and the step of exchanging the gas alternatively via the step of purging the gas. At this point, forming a film can also be performed effectively. In other words, the improvement of the film formation rate can be gotten with less gas consumption.

(d) According to the first embodiment, the undersurface of each gas distribution assembly 25 which configures the process gas supplying system or inert gas supplying system is opposed with wafer W placed on susceptor 10 and the undersurface of each gas distribution assembly 25 is arranged to become parallel to the receiving surface of wafer W on susceptor 10. Therefore, a process gas (TiCl4 gas or NH3 gas) or an inert gas (NH3 gas) injected from gas supplying path 253 in gas distribution assembly 25 can spread through the space between the undersurface of gas distribution assembly 25 and top surface of wafer W. By this, forming a film on wafer W can be performed appropriately under the restraint of the partial deflection of exposure to gases on wafer W.

(e) According to the first embodiment, the width at the rotatory direction of exhausting buffer 255 is gradually increased from the inner side toward the opposing outer side. By this, exhaust efficiency at outer side of exhausting buffer 255 becomes higher than that of inner side. Therefore, when the gases in exhausting buffer 255 is exhausted toward the side depositing exhausting holes 231 (in other words, toward the outer side of susceptor 10), the gases can flow from the inner side to the outer side in exhausting buffer 255 positively, then exhausting gases from exhausting buffer 255 can perform effectively. Specifically, even if reaction byproducts or remaining gases have been flowed into exhausting buffer 255, the reaction byproducts or remaining gases can exhausted to outside positively, then deposition or adsorption causing those remaining gases or byproducts can be reduced.

(f) According to the first embodiment, gas distribution assembly 25 may come to a convex-shape formed by first member 251 and second member 252, looked from the radial direction. Therefore, when unexpected films are formed in exhausting buffer 255 and such unexpected films are in condition to be easy to come off, the films which come off the wall of exhausting buffer 255 may fall on the wide part of second member 252, then spreading unexpected films, which come off the wall of exhausting buffer 255, on the surface of wafer W can be reduced. In other words, exhausting buffer 255 may be configured by gas distribution assembly 25 which generally has convex shapes in a lateral shape.

(g) According to the first embodiment, gas distribution assemblies 25 may be arranged so that gas distribution assembly 25c may be disposed at the position between gas distribution assembly 25a and gas distribution assembly 25b. In this way, the air seal caused by the inert gas may be generated in the space defined between top surface of wafer W and undersurface of gas distribution assembly 25c. Therefore, the condition that different types of process gases (source gases or reactant gases) are mixed on the surface of wafer W, can be reduced when wafers W on susceptor 10 are passed through under each gas distribution assembly 25 in the step of forming a film (S103).

(h) According to the first embodiment, each gas distribution assembly 25a, 25b is configured to supply different type of gas respectively. In other words, gas supplying path 253 in gas distribution assembly 25a connected to source gas supplying conduit 311 may supply the source gas (titanium tetrachloride (TiCl4) gas) to the surface of wafer W and gas supplying path 253 in gas distribution assembly 25b connected to source gas supplying conduit 321 may supply the reactant gas (ammonia (NH3) gas) to the surface of wafer W. Therefore, when wafers W are passed through under gas distribution assembly 25a, 25b sequentially, a titanium nitride (TiN) film may be formed without exchanging process gases or purging gases. Then, throughput of forming a film can be improved.

### The Second Embodiment of the Present Disclosure

Hereinafter, the second embodiment of the present disclosure will be described with reference to the drawings. The difference with the first embodiment mentioned above may be explained mainly.

Configuration of a Substrate Processing Apparatus According to the Second Embodiment

In the substrate processing apparatus according to the second embodiment, a gas distribution assembly 25 may have a different configuration in comparison with the case of the first embodiment.

(Gas Distribution Assembly)

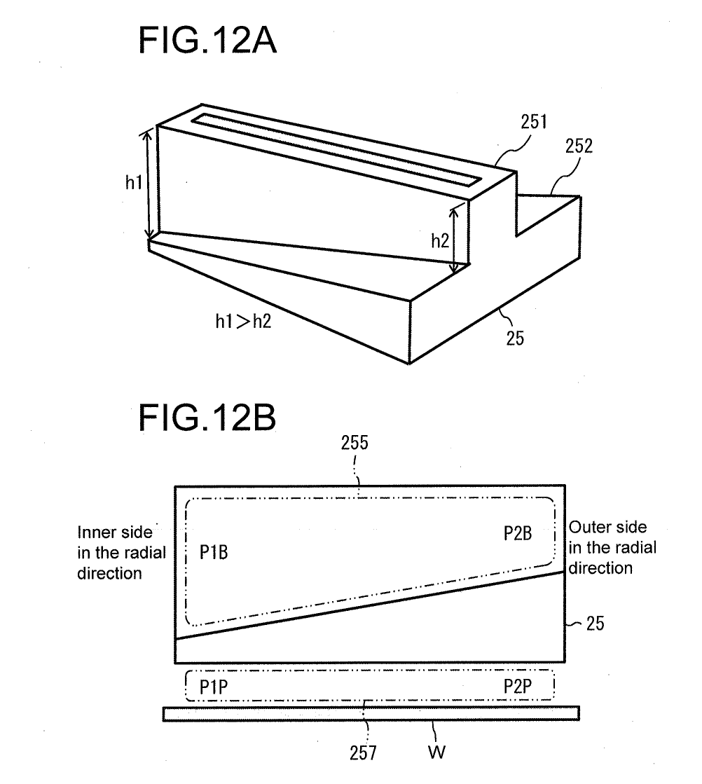

FIG. 12A is a perspective view of a gas distribution assembly 25 used in the substrate processing apparatus according to a second embodiment of the present disclosure. FIG. 12B is a side view of the gas distribution assembly 25 used in the substrate processing apparatus according to the second embodiment of the present disclosure, showing a pressure balance in an exhausting buffer.

As shown in FIG. 12A, gas distribution assembly 25 is set forth by way of explanation, top surface of second member 252 which defines the bottom surface of exhausting buffer 255 may be disposed at a slant so that the relation of inner height h1 and outer height h2 of first member 251 which configures the side wall of exhausting buffer 255 may become h1>H2. In this exhausting buffer 255 according to this configuration, the air volume of inner side of exhausting buffer 255 may increase to greater than that of outer side of exhausting buffer 255. By employing such a gas distribution assembly 25, the distance between the gas exhausting aperture 254 defined by gas distribution assembly 25 and gas exhausting buffer 255 may gradually change from the inner side for the outer side. Specifically, the distance between gas exhausting aperture 254 and gas exhausting buffer 255 may become gradually longer. Therefore, there may also be the difference of the gas flowing conductance from gas exhausting aperture 254 to gas exhausting buffer 255, between the inner side and outer side. The gas from gas exhausting aperture to gas exhausting buffer may become hard to flow through outer side than inner side.

(Gas Flows in the Processing to Supply or Exhaust Gas)

Hereinafter, the gas flows through gas exhausting aperture 254, toward upper side of wafer W is disclosed in the second embodiment of the present disclosure. FIG. 12B is a side view of the gas distribution assembly 25 used in the substrate processing apparatus according to the second embodiment of the present disclosure, showing a pressure balance in exhausting buffer 255. The pressure balance between the inner and outer side of the space 256 located under gas distribution assembly 25 may depend on a shape or size of gas exhausting aperture 254 or gas exhausting buffer 255. For example, if the air volume of outer side of exhausting buffer 255 is larger than that of inner side of exhausting buffer 255 extremely, the pressure balance between P1P and P2P might maintain the state that P1P>P2B in spite of disposing exhausting buffer 255. In this case, if the relation of inner height h1 and outer height h2 of first member 251 which configures the side wall of exhausting buffer 255 becomes h1>H2, since the conductance of inner side, from gas exhausting aperture 254 to gas exhausting buffer 255, may become higher than that of outer side, the pressure P1P relatively lowers in comparison with the pressure in the state that the gas flowing conductance between the inner side and outer side, from gas exhausting aperture 254 to gas exhausting buffer 255 is same.
In this way, the difference between inner side and outer side of pressure can be lowered, then, P1P can be equated with P2P generally. When P1P is generally equated with P2P, the distribution of the film thickness of the titanium nitride (TiN) film formed on wafer W may become good because the deviations of film thickness may be suppressed.

### Effect in the Second Embodiment

For example, one or more effects in the second embodiment are shown below.

(i) According to the second embodiment, the gas flowing conductance from gas exhausting aperture 254 to gas exhausting buffer 255 may be different between the inner side and outer side in the radial direction of susceptor 10. Specifically, the height of exhausting buffer 255 may be changed continuously or step by step from the inner side to outer side in the radial direction of susceptor 10, then the distance between gas exhausting aperture 254 and gas exhausting buffer 255 may change continuously or step by step from the inner side to outer side in the radial direction of susceptor 10. In this way, the gas flowing conductance at the inner side of gas exhausting buffer 255 becomes higher than the gas flowing conductance at the outer side of gas exhausting buffer 255. Therefore, regardless of the shape or size of gas exhausting aperture 254 or exhausting buffer 255, the pressure difference between P1P and P2P at the space 256 located under gas distribution assembly 25 can be lower in comparison with the case of the first embodiment and uniformity of the surface of wafer W may be improved still more.

### The Third Embodiment of the Present Disclosure

Hereinafter, the third embodiment of the present disclosure will be described with reference to the drawings. The difference with the first or second embodiment mentioned above may be explained mainly.

Configuration of a Substrate Processing Apparatus According to the Third Embodiment

In the substrate processing apparatus according to the third embodiment, the gas exhausting system may support the system for exhausting gases toward inner side of center cylindrical member 24, not supporting the system for exhausting gases toward outer side of inner cylindrical member 23, disclosed in the first embodiment. Specifically, in the substrate processing apparatus according to a third embodiment, each of exhausting holes 231 for communicating with exhausting buffer 255 may be opened at the wall of center cylindrical member 24 and gas exhausting port 26 may be disposed at center cylindrical member 24, so that the gases in exhausting buffer 255 are exhausted toward the inner side of gas cartridge head 20.

Furthermore, in the substrate processing apparatus according to a third embodiment, gas distribution assembly 25 in cartridge head 20 is different from the case of first embodiment or second embodiment.

(Gas Distribution Assembly)

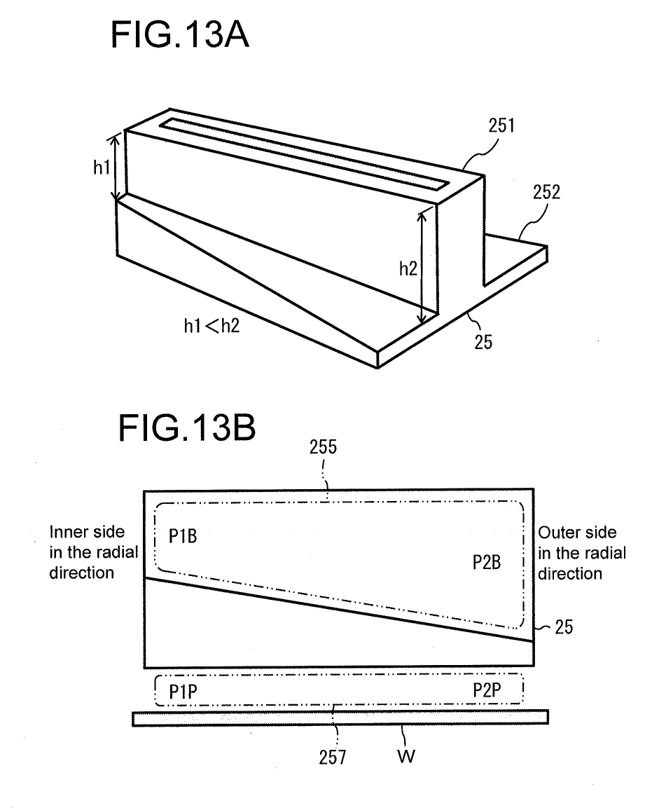

FIG. 13A is a perspective view of a gas distribution assembly 25 used in the substrate processing apparatus according to the third embodiment of the present disclosure.
FIG. 13B is a side view of the gas distribution assembly 25 used in the substrate processing apparatus according to the third embodiment of the present disclosure, showing a pressure balance in an exhausting buffer.
As shown in FIG. 13A, gas distribution assembly 25 to explain here, top surface of second member 252 which defines the bottom surface of exhausting buffer 255 may be slanted in the direction where is reverse to the slant in case of the second embodiment so that the relation of inner height h1 and outer height h2 of first member 251 which configures the side wall of exhausting buffer 255 may become h1<H2. In this exhausting buffer 255 according to this configuration, the air volume of outer side of exhausting buffer 255 may increase than that of inner side of exhausting buffer 255, in comparison with the case of the first embodiment. By employing such a gas distribution assembly 25, the distance between the gas exhausting aperture 254 defined by gas distribution assembly 25 and gas exhausting buffer 255 may gradually change from the inner side for the outer side. Specifically, the distance between gas exhausting aperture 254 and gas exhausting buffer 255 may become gradually shorter. Therefore, there may also be the difference of the gas flowing conductance between the inner side and outer side, from gas exhausting aperture 254 to gas exhausting buffer 255. The gas from gas exhausting aperture to gas exhausting buffer may become easy to flow through outer side than inner side.

(Gas Flows in the Processing to Supply or Exhaust Gas)

Hereinafter, the gas flows through gas exhausting aperture 254, toward upper side of wafer W is disclosed in the third embodiment of the present disclosure. When the gas exhausting system of substrate processing apparatus supports the system for exhausting gases toward inner side of center cylindrical member 24, the pressure balance between inner side and outer side of exhausting buffer 255 may become P1B<P2B as shown FIG. 13B. When the pressure balance between inner side and outer side of exhausting buffer 255 is P1B<P2B, there may be a difference of exhaust efficiency between inner side and outer side, at the space 256 under gas distribution assembly 25. As a result, the pressure of outer side (P2P) may become higher and the deviations of film thickness on wafer W may be generated easily. In this case, if the relation of inner height h1 and outer height h2 of first member 251 which configures the side wall of exhausting buffer 255 becomes h1<H2, since the conductance of outer side, from gas exhausting aperture 254 to gas exhausting buffer 255, may become higher than that of inner side, the pressure P2P relatively lowers in comparison with the pressure in the state that the gas flowing conductance between the inner side and outer side, from gas exhausting aperture 254 to gas exhausting buffer 255 is same. In this way, the differences between inner side and outer side of pressure can be lowered, then, P1P can be equated with P2P generally. When P1P is generally equated with P2P, the distribution of the film thickness of the titanium nitride (TiN) film formed on wafer W may become good because the deviations of film thickness may be suppressed.

### Effect in the Third Embodiment

For example, one or more effects in the third embodiment are shown below.

(j) According to the third embodiment, the gas flowing conductance from gas exhausting aperture 254 to gas exhausting buffer 255 may be different between the inner side and outer side in the radial direction of susceptor 10. Specifically, the height of exhausting buffer 255 may be changed continuously or step by step from the inner side to outer side in the radial direction of susceptor 10, then the distance between gas exhausting aperture 254 and gas exhausting buffer 255 may be changed continuously or step by step from the inner side to outer side in the radial direction of susceptor 10. In this way, the gas flowing conductance at the outer side of gas exhausting buffer 255 becomes higher than the gas flowing conductance at the inner side of gas exhausting buffer 255. Therefore, for example, when the gas exhausting system of the substrate processing system supports the system for exhausting gases toward inner side of center cylindrical member 24, the pressure difference between P1P and P2P at the space 256 located under gas distribution assembly 25 can be lower and uniformity of the surface of wafer W may be improved still more.

### The Fourth Embodiment of the Present Disclosure

Hereinafter, the fourth embodiment of the present disclosure will be described with reference to the drawings. The difference with the first, second or third embodiment mentioned above may be explained mainly.

(Configuration of a Substrate Processing Apparatus According to the Fourth Embodiment)

In the substrate processing apparatus according to the fourth embodiment, the gas exhausting system may have a different configuration in comparison with the case of the first, second or third embodiment.

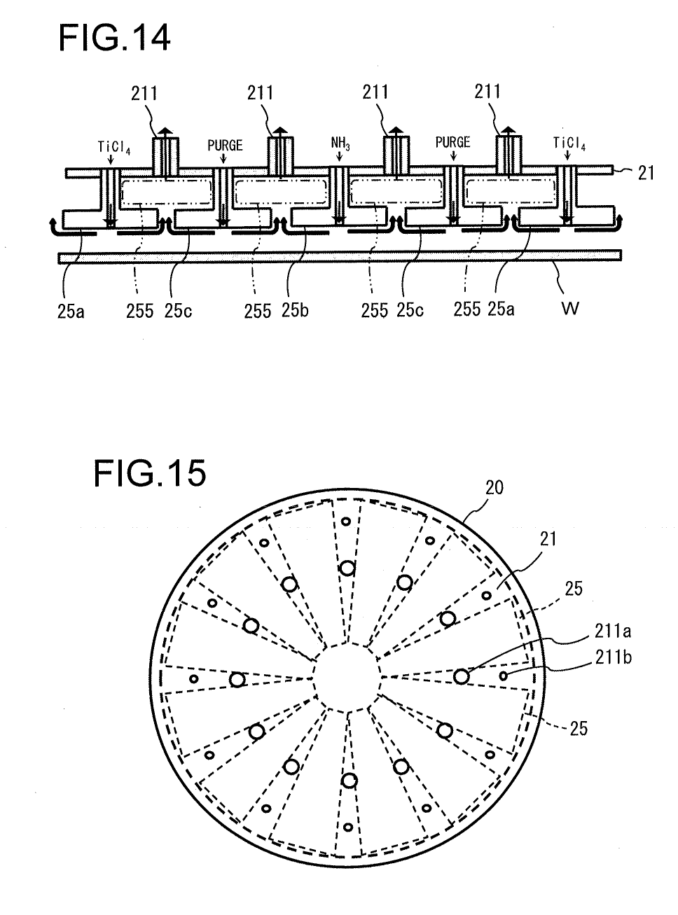

Hereinafter, the configuration of a substrate processing apparatus according to the fourth embodiment is explained with reference to FIG. 14 to FIG. 16.

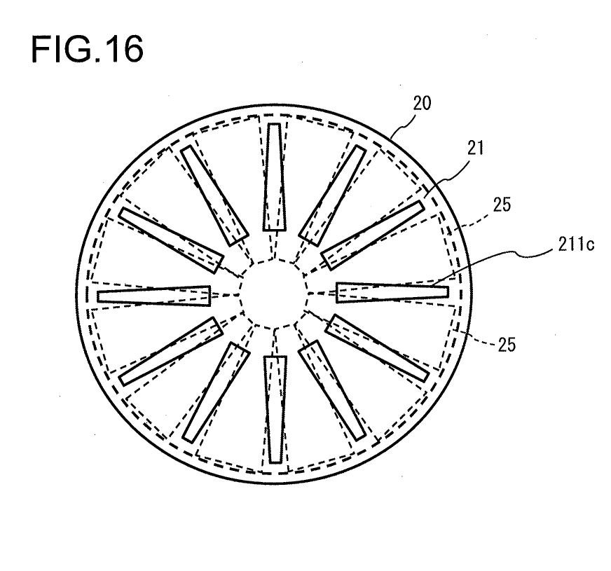

FIG. 14 is a side cross-sectional view showing main parts of the substrate processing apparatus according to the fourth embodiment of the present disclosure. FIG. 15 is a plan cross-sectional view showing main parts of the substrate processing apparatus according to the fourth embodiment of the present disclosure. FIG. 16 is a plan cross-sectional view showing main parts of the substrate processing apparatus according to another aspect of the fourth embodiment of the present disclosure.

(Gas Exhausting System)

As shown in FIG. 14, gas exhausting port 211 for communicating with exhausting buffer 255 may be disposed at ceiling part 21 of cartridge head 20 in the substrate processing apparatus according to the fourth embodiment. Gas exhausting ports 211 may be disposed at ceiling part 21 in response to each of plural exhausting buffers 255. Gas exhausting ports 211 may be connected to gas exhausting conduit 341 configuring the gas exhausting system. Due to applying such a gas exhausting port 211 in the fourth embodiment, gas exhausting port 26 and exhausting holes 231 which are disclosed in the first embodiment are not applied.

Gas exhausting port 211 may be disposed so that plural ones are arranged along a radial direction of cartridge head 20 per one exhausting buffer 255 as shown FIG. 15. For example, FIG. 15 shows two (2) gas exhausting port 211a, 211b. These plural gas exhausting ports 211a, 211b may be formed so that they have a different conductance when gases are flowing through them. Specifically, the opening aperture of gas exhausting port 211a disposed at inner side of exhausting buffer 255 may be bigger than that of gas exhausting port 211b disposed at outer side of exhausting buffer 255.

Gas exhausting port 211 may cause a different conductance between inner side and outer side of exhausting buffer 255. Then, it is not limited to the configuration that some ports which have a different size of aperture are formed along a radial direction. As a gas exhausting port 211, for example, gas exhausting port 211c may be shaped into the plane trapezoid-shape, width of inner side is wider than that of outer side in a circumference direction, as shown in FIG. 16.

(Gas Flows in the Processing to Supply or Exhaust Gas)

Hereinafter, gas flows toward upper side of wafer W, through gas exhausting aperture 254, exhausting buffer 255 and gas exhausting port 211, is disclosed in detail in the fourth embodiment.
The gases supplied to the surface of wafer W may flow in exhausting buffer 255 through gas exhausting aperture 254, then the gases may be exhausted from exhausting buffer 255 to outside of cartridge head 20 through gas exhausting port 211. In this case, gas exhausting port 211 may be configured so that the conductance of the port arranged at inner side of exhausting buffer 255 may become larger than that of the port arranged at outer side of exhausting buffer 255. Therefore, exhausting gases at inner side of exhausting buffer 255 may be promoted than exhausting gases at outer side of exhausting buffer 255. The pressure P1P at the inner side of exhausting buffer 255 relatively lowers in comparison with the pressure in the state that the gas flowing conductance between the inner side and outer side is same. In this way, the difference between inner side and outer side of pressure can be lowered, then, P1P can be equated with P2P generally. When P1P is generally equated with P2P, the distribution of the film thickness of the titanium nitride (TiN) film formed on wafer W may become good because the deviations of film thickness may be suppressed.

### Effect in the Fourth Embodiment

For example, one or more effects in the fourth embodiment are shown below.

(k) According to the fourth embodiment, gas exhausting ports 211 may be configured so that there are differences of gas flowing conductance when gases are exhausted from gas exhausting buffer 255 through gas exhausting ports 211. Specifically, gas exhausting ports 211 are configured so that the gas flowing conductance at the inner side becomes higher than the gas flowing conductance at the outer side of gas exhausting buffer 255. Therefore, regardless of the shape or size of gas exhausting aperture 254 or exhausting buffer 255, the pressure difference between PIP and P2P at the space 256 located under gas distribution assembly 25 can be lower in comparison with the case of the first embodiment and uniformity of the surface of wafer W may be improved still more.

(l) According to the fourth embodiment, gas exhausting port 211 may be disposed at ceiling part 21 of cartridge head 20, then a plurality of gas exhausting ports 211 may be disposed along a radial direction of cartridge head 20 per one exhausting buffer 255 or gas exhausting port 211, which is shaped into the plane trapezoid-shape, width of inner side is wider than that of outer side in a circumference direction, may be disposed along a radial direction. Therefore, the gases in exhausting buffer 255 can be scattered to inner side or outer side in a circumference direction and the concentration of flowing gases that may be expected under the condition that the gases in exhausting buffer 255 are exhausted through exhausting holes 231 disposed just only inner cylindrical member 23 as shown in FIG. 4 in the first embodiment. In other words, by reducing the concentration of flowing gases in exhausting gases, exhaust efficiency may also be improved at the inner side in a circumference direction of exhausting buffer 255.

### The Fifth Embodiment of the Present Disclosure

Hereinafter, the fifth embodiment of the present disclosure will be described with reference to the drawings. The difference with the first, second, third and fourth embodiment mentioned above may be explained mainly.

(Configuration of a Substrate Processing Apparatus According to the Fifth Embodiment)

In the substrate processing apparatus according to the fifth embodiment, the gas exhausting system may have a different configuration in comparison with the case of the first, second, third or fourth embodiment.

(Gas Exhausting System)

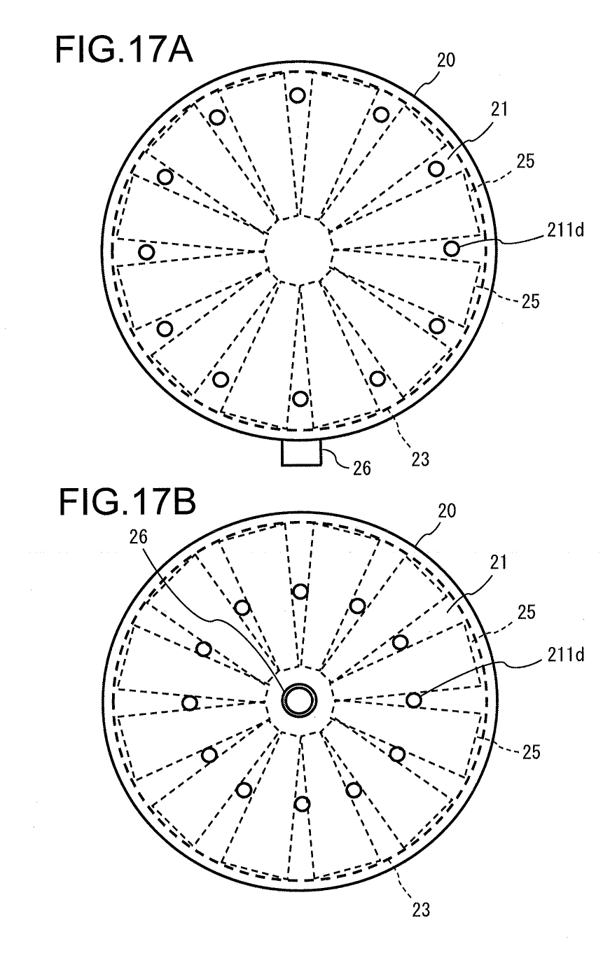

FIG. 17A and FIG. 17B is a plan cross-sectional view showing main parts of the substrate processing apparatus according to a fifth embodiment of the present disclosure. As shown in FIG. 17A, gas exhausting port 211 for communicating with exhausting buffer 255 may be disposed at ceiling part 21 of cartridge head 20 in the substrate processing apparatus according to the fifth embodiment. Unlike the case of the fourth embodiment, at least one gas exhausting ports 211d may be disposed at ceiling part 21 in response to each of plural exhausting buffer 255. Specifically, just one gas exhausting port 211d may be disposed at the outer position of cartridge head 20 in response to each of plural exhausting buffers 255.

In addition, cartridge head 20 may include gas exhausting port 26 in addition to gas exhausting port 211d like the case of the first embodiment. The gases in exhausting buffer 255 are exhausted to outside of gas cartridge head 20 through gas exhausting port 26 and exhausting holes 231.

The substrate processing apparatus disclosed in the fifth embodiment is not limited to the system for exhausting gases toward outer side of inner cylindrical member 23 disclosed in the first embodiment, but the system for exhausting gases toward inner side of center cylindrical member 24 disclosed in the third embodiment may be included in the fifth embodiment as well. In this case, gas exhausting port 26 may be disposed at center cylindrical member 24 in cartridge head 20 as shown in FIG. 17B. At least one gas exhausting port 211d may also be disposed at ceiling part 21 in response to each of plural exhausting buffer 255. Specifically, just one gas exhausting port 211d may be disposed at the inner position of cartridge head 20 in response to each of plural exhausting buffers 255.

(Gas Flows in the Processing to Supply or Exhaust Gas)

Hereinafter, flow of the gas when exhausting from exhausting buffer 255 is disclosed in detail in the fifth embodiment.

For example, as shown in FIG. 17A, when the gas exhausting system in the substrate processing apparatus supports the system for exhausting gases toward outer side of inner cylindrical member 23, the gases in exhausting buffer 255 may be exhausted to outside of cartridge head 20, through exhausting holes 231 and gas exhausting port 26, and also exhausted to upper side of cartridge head 20 through gas exhausting ports 211d. Therefore, the conductance of inner side may become higher as much as the exhaustion based on exhausting gases through exhausting holes 231 than the case merely exhausting gases toward outer side of inner cylindrical member 23. Therefore, exhausting gases at inner side of exhausting buffer 255 may be promoted than exhausting gases at outer side of exhausting buffer 255. The pressure P1P at the inner side of exhausting buffer 255 relatively lowers in comparison with the pressure in the state that the gas flowing conductance between the inner side and outer side is same. In this way, the difference between inner side and outer side of pressure can be lowered, then, P1P can be equated with P2P generally. When P1P is generally equated with P2P, the distribution of the film thickness of the titanium nitride (TiN) film formed on wafer W may become good because the deviations of film thickness may be suppressed.

In addition, as shown in FIG. 17B, when the gas exhausting system in the substrate processing apparatus supports the system for exhausting gases toward inner side of center cylindrical member 24, the gases in exhausting buffer 255 may be exhausted to inner side of cartridge head 20 and also exhausted to upper side of wafer W through gas exhausting ports 211d. Therefore, the conductance of outer side may become higher as much as the exhaustion based on exhausting gases through exhausting ports 211d than the case merely exhausting gases toward inner side of center cylindrical member 24. Therefore, exhausting gases at outer side of exhausting buffer 255 may be promoted than exhausting gases at inner side of exhausting buffer 255. The pressure P2P at the outer side of exhausting buffer 255 relatively lowers in comparison with the pressure in the state that the gas flowing conductance between the inner side and outer side is same. In this way, the pressure difference between at the inner side and outer side can be lowered, then, P1P can be equated with P2P generally. When P1P is generally equated with P2P, the distribution of the film thickness of the titanium nitride (TiN) film formed on wafer W may become good because the deviations of film thickness may be suppressed.

### Effect in the Fifth Embodiment

For example, one or more effects in the fifth embodiment are shown below.

(m) According to the fifth embodiment, as the gases in exhausting buffer 255 are additionally exhausted toward the upper side of cartridge head 20 under the condition that the gases in exhausting buffer 255 are exhausted toward the outer or inner side of cartridge head 20, the difference of gas flowing conductance between at the inner side and outer side of exhausting buffer 255 can be controlled. Therefore, in the case that the gas exhausting system in the substrate processing apparatus supports the system for exhausting gases toward inner side of center cylindrical member 24 or toward outer side of inner cylindrical member 23, the pressure difference between at the inner side and outer side of exhausting buffer 255 can be lowered and uniformity of the surface of wafer W may be improved still more.

### Other Embodiments of Present Disclosure

It will be understood by those of skill in the art that numerous and various modifications can be made without departing from the spirit of the present disclosure. Therefore, it should be clearly understood that the forms of the present disclosure are illustrative only and are not intended to limit the scope of the present disclosure.

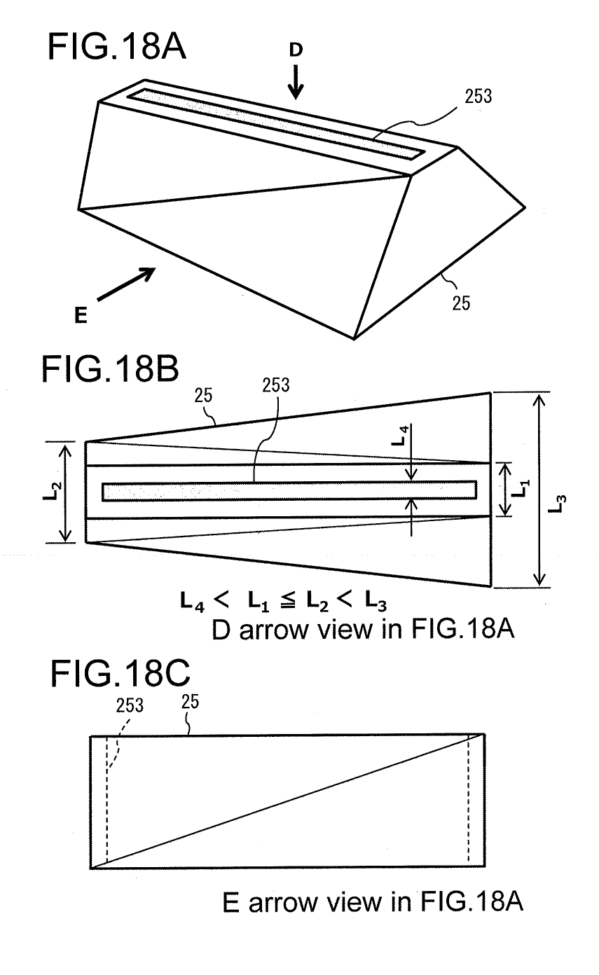

For example, a lateral shape of gas distribution assembly 25 is disclosed as a convex-shape under consideration for manufacturing it easily in each above-mentioned embodiment. But it is not limited to this convex-shape. In other words, the shape of gas distribution assembly 25 should be configured to form exhausting buffer 255. For example, corner 251a disclosed in FIG. 2B may be rounded so as to have a R-shaped corner. Furthermore, gas distribution assembly 25 may not only be formed into a convex-shape in a lateral shape. Gas distribution assembly 25 may also be defined by the slant faces to constitute the side and bottom walls of exhausting buffer 255 so as to configure gas exhausting buffer 255 as shown in FIG. 18.

In the above-mentioned embodiments, for example, the relative position between wafer W on susceptor 10 and cartridge head 20 is moved by the rotation of susceptor 10 or cartridge head 20. But the movement of relative position between wafer W on susceptor 10 and cartridge head 20 is not limited to the rotation of susceptor 10 or cartridge head 20. In other words, the configuration of the substrate processing apparatus should be configured to move the relative position between wafer W and a gas supplying system. It is not limited to a rotating system like the substrate processing apparatus disclosed in each embodiment, but a linear-type system employing the linear-type configuration like a conveyor can be applied to the movement of relative position between wafer W and a gas supplying system.

In the above-mentioned embodiments, gas distribution assembly 25c for supplying an inert gas (N2 gas) is arranged between gas distribution assembly 25a for supplying a source gas and gas distribution assembly 25b for supplying a reactant gas. The arrangement of gas distribution assemblies 25 is not limited to this arrangement. For example, gas distribution assembly 25c for supplying an inert gas (N2 gas) may be arranged between two gas distribution assemblies 25b for supplying reactant gases. In this case, a source gas may be supplied into the process chamber by employing a gas supplying system which supplies the source gas from the direction except the upper side of wafer W instead of gas distribution assembly 25a. For example, an aperture for supplying a source gas may be disposed at the center of process chamber.

In addition, in the above-mentioned embodiments, gas supply assembly 25c for supplying an inert gas (N2 gas) is arranged between gas distribution assembly 25a for supplying a source gas and gas distribution assembly 25b for supplying a reactant gas. The arrangement of gas distribution assemblies 25 is not limited to this arrangement. For example, gas supply assembly 25c for supplying an inert gas (N2 gas) may be arranged between two gas distribution assemblies 25a for supplying source gases. In this case, a reactant gas may be supplied into the process chamber by employing a gas supplying system which supplies the reactant gas from the direction except the upper side of wafer W instead of gas distribution assembly 25c. For example, an aperture for supplying a reactant gas may be disposed at the center of process chamber.

In addition, in the above-mentioned embodiments, a process for forming a titanium nitride (TiN) film on wafer W by employing the substrate processing apparatus, by supplying titanium tetrachloride (TiCl4) gas as a source gas (a first process gas) and ammonia (NH3) gas as a reactant gas (a second process gas) alternatively is disclosed. The process is not limited to this process. In other words, process gases for forming a film are not limited to titanium tetrachloride (TiCl4) gas or ammonia (NH3) gas. By using other types of gases, other types of films may be formed. Furthermore, forming a film by supplying more than three kind of gases may be applied to the scope of the present disclosure.this invention.

While foregoing is directed to the process forming a film as a process employing the substrate processing apparatus, the disclosure is not limited to this process. For example, this apparatus can be applicable to forming the oxide film, nitride film or other metal-containing film except titanium nitride (TiN) film exemplified in this embodiment. In addition, this apparatus can also be applicable to other substrate processes such as a diffusion process, oxidation, nitriding. In addition, this invention is applicable to a film formation apparatus, etching equipment, oxidation processing member, nitrided processing member, other substrate processing member such as a coating applicator, drying apparatus, the heating apparatus, plasma processing apparatus.

In addition, an element of a certain embodiment can be replaced by another element of other embodiment, and the configuration of other embodiment can be added to the configuration of a certain embodiment. In addition, a part of the configuration of each embodiment, addition, deletion of other configuration can be substituted.

Hereinafter, preferred embodiments of the present disclosure will be appended.

### Embodiment Note 1

Pursuant to the present disclosure, there is provided a substrate processing apparatus including:

a susceptor configured to place a substrate on it;
a process gas distribution assembly configured to supply a process gas on a surface of the substrate from the upper side of the susceptor;
an inert gas distribution assembly arranged next to the process gas distribution assembly, configured to supply an inert gas on the surface of the substrate from the upper side of the susceptor; and
a gas exhausting system including following (a) and (b),
(a) a gas exhausting aperture arranged between the process gas distribution assembly and the inert gas distribution assembly, corresponding to the susceptor,
(b) an exhausting buffer for holding the gases passed through the gas exhausting aperture,
wherein the gas exhausting system is configured to exhaust gases supplied on the surface of the substrate to the upper side via the gas exhausting aperture and the exhausting buffer.

### Embodiment Note 2

In the substrate processing apparatus of Embodiment note 1, the susceptor may be disposed rotatable in a state where a plurality of substrates are put on it, the process gas distribution assembly or the inert gas distribution assembly having a fan-shaped or trapezoid-shaped undersurface spreading for the outside from the pivot side of the susceptor.

### Embodiment Note 3

In the substrate processing apparatus of Embodiment note 2, the process gas distribution assembly or the inert gas distribution assembly may be arranged so that the undersurface of each member may be parallel to the substrate receiving surface of the susceptor.

### Embodiment Note 4

In the substrate processing apparatus of Embodiment note 2 or 3, wherein the width of the gas exhausting buffer in the rotatory direction of the susceptor may be gradually increased from the inner side to the outer side of the radial direction of the gas exhausting buffer.

### Embodiment Note 5

In the substrate processing apparatus of Embodiment note 2 to 4, wherein the gas exhausting system is configured to flow gases with a different conductance between the inner side and the outer side of the gas exhausting aperture or the gas exhausting buffer in the radial direction of the susceptor.

### Embodiment Note 6

In the substrate processing apparatus of Embodiment note 5, wherein the exhaust buffer may be formed so that the height of exhausting buffer may be changed continuously or step by step from the inner side to outer side in the radial direction of exhausting buffer.

### Embodiment Note 7

In the substrate processing apparatus of Embodiment note 5 or 6, wherein the gas exhausting system may be configured so that the distance from the gas exhaust aperture to the exhaust buffer may be changed continuously or step by step from the inner side to outer side in the radial direction of the gas exhausting system.

### Embodiment Note 8

Pursuant to still another disclosure, there is provided a method of manufacturing a semiconductor device, the method comprising:

exposing a substrate set on a susceptor to a process gas supplied from the upper side of the susceptor by employing a process gas distribution assembly arranged above the susceptor;

exposing the substrate to an inert gas supplied from the upper side of the susceptor by employing an inert gas distribution assembly arranged above the susceptor; and

exhausting gases upward from the surface of the substrate through a gas exhausting aperture and an exhausting buffer for holding gases passed the gas exhausting aperture, wherein the gas exhausting aperture is formed between the process gas distribution assembly and the inert gas distribution assembly, corresponding to the susceptor.

### Embodiment Note 9

Pursuant to still another disclosure, there is provided a cartridge head, which may be arranged to be opposed to the substrate receiving surface, at the upper side of the susceptor, the cartridge head comprising:

a process gas distribution assembly configured to supply a process gas on a surface of the substrate from the upper side of the susceptor;
an inert gas distribution assembly arranged next to the process gas distribution assembly, configured to supply an inert gas on the surface of the substrate from the upper side of the susceptor; and
a gas exhausting system including following (a) and (b),

(a) a gas exhausting aperture formed between the process gas distribution assembly and the inert gas distribution assembly, corresponding to the susceptor,

(b) an exhausting buffer for holding the gases passed through the gas exhausting aperture,

wherein the gas exhausting system is configured to exhaust gases supplied on the surface of the substrate to the upper side via the gas exhausting aperture and the exhausting buffer.

### Embodiment Note 10

Pursuant to still another disclosure, there is provided a gas distribution assembly which may be arranged to be opposed to the upper side of the substrate, the gas distribution assembly comprising:

a gas supplying path configured to supply a gas to the substrate;

a first member configured to surround the upper side of the gas supplying path; and

a second member configured to surround the lower side of the gas supplying path, the plane shape of the second member is wider than that of the first member,

wherein when the gas distribution assembly is arranged at the upper side of a substrate, the gas distribution assembly configures a part of the gas exhausting buffer for holding gases passed through the gas exhausting aperture defined by the side wall of the second member, and the gas distribution assembly configures a part of the exhausting buffer defined by the side wall of the first member and the upper wall of the wide part of the second member.

### Embodiment Note 11

Pursuant to still another disclosure, there is provided a program for manufacturing a semiconductor device by employing a substrate processing apparatus, the program causing a substrate processing apparatus to execute:

exposing a substrate set on a susceptor to a process gas supplied from the upper side of the susceptor by employing a process gas distribution assembly arranged above the susceptor;

exposing the substrate to an inert gas supplied from the upper side of the susceptor by employing an inert gas distribution assembly arranged above the susceptor; and

exhausting gases upward from the surface of the substrate through a gas exhausting aperture and an exhausting buffer for holding gases passed the gas exhausting aperture, wherein the gas exhausting aperture is formed between the process gas distribution assembly and the inert gas distribution assembly, corresponding to the susceptor.

### Embodiment Note 12

Pursuant to still another disclosure, there is provided a non-transitory computer-readable recording medium storing a program for manufacturing a semiconductor device by employing a substrate processing apparatus, the program causing a substrate processing apparatus to execute:

exposing a substrate set on a susceptor to a process gas supplied from the upper side of the susceptor by employing a process gas distribution assembly arranged above the susceptor;

exposing the substrate to an inert gas supplied from the upper side of the susceptor by employing an inert gas distribution assembly arranged above the susceptor; and

exhausting gases upward from the surface of the substrate through a gas exhausting aperture and an exhausting buffer for holding gases passed the gas exhausting aperture, wherein the gas exhausting aperture is formed between the process gas distribution assembly and the inert gas distribution assembly, corresponding to the susceptor.

### Embodiment Note 13

Pursuant to still another disclosure, inert gas distribution assembly 25c can be omitted appropriately under the consideration of throughput of the film formation. In this case, gas exhausting aperture 254 and exhausting buffer 255 are formed between source gas distribution assembly 25a and reactant gas distribution assembly 25b.

There is provided a substrate processing apparatus including: a susceptor configured to place a substrate on it;
a source gas distribution assembly configured to supply a source gas on a surface of the substrate from the upper side of the susceptor;
a reactant gas distribution assembly arranged next to the source gas distribution assembly, configured to supply an reactant gas on the surface of the substrate from the upper side of the susceptor; and
a gas exhausting system including following (a) and (b),

(a) a gas exhausting aperture formed between the source gas distribution assembly and the reactant gas distribution assembly, corresponding to the susceptor,

(b) an exhausting buffer for holding the gases passed through the gas exhausting aperture,

wherein the gas exhausting system is configured to exhaust gases supplied on the surface of the substrate to the upper side via the gas exhausting aperture and the exhausting buffer.

### Embodiment Note 14

Pursuant to still another disclosure, there is provided a substrate processing apparatus including:

a susceptor configured to place a substrate on it;
a process gas distribution assembly including a rectangular through-hole for supplying a process gas to the substrate from an upper side of the susceptor, the length in the longitudinal direction of the through-hole is longer than or equal with the diameter of the substrate, the process gas distribution assembly including a projecting part extending outwardly from the through-hole;
an inert gas distribution assembly, arranged next to the process gas distribution assembly, an inert gas distribution assembly including a rectangular through-hole for supplying an inert gas to the substrate from an upper side of the susceptor, the length in the longitudinal direction of the through-hole is longer than or equal with the diameter of the substrate, the inert gas distribution assembly including a projecting part extending outwardly from the through-hole; and a gas exhausting system including a gas exhausting aperture defined between the process gas distribution assembly and the inert gas distribution assembly, the gas exhausting system including an exhausting buffer, partly defined by the upper walls of the projecting parts and side walls of the gas distribution assemblies next to each other,
wherein the gas exhausting system is configured to exhaust a gas being in the domain sandwiched between the bottom surface of projecting part and the corresponding region of susceptor, through the exhausting buffer via the gas exhausting aperture.

### Embodiment Note 15

Pursuant to still another disclosure, there is provided a gas distribution assembly for a substrate processing apparatus, the gas distribution assembly includes a first member formed into a hollow rectangular solid shape and a second member formed into a fan-shaped or trapezoid-shaped plate having a rectangular through-hole communicated with hollow part of the first member, wherein a length in the longitudinal direction of the through-hole is longer than or equal with the diameter of a substrate, the second member has a projecting part extending outwardly from the through-hole in the fan or trapezoidal direction spreading out, the second member being attached to the bottom of first member.

1. A substrate processing apparatus comprising:
a susceptor configured to receive a substrate on a substrate receiving surface of the susceptor;
a cartridge head disposed at the upper side of the susceptor, including a ceiling part;
a plurality of gas distribution assemblies comprising:
a process gas distribution assembly including a rectangular through-hole for supplying a process gas to the substrate to be received from an upper side of the susceptor, the length in the longitudinal direction of the through-hole is longer than or equal with the diameter of the substrate to be received, the process gas distribution assembly including a projecting part extending outwardly from the through-hole, wherein the process gas distribution assembly is suspended from the ceiling part of the cartridge head and the rectangular through-hole extends toward the susceptor from an outer edge of the ceiling part through the ceiling part and through the projecting part of the process gas distribution assembly;
an inert gas distribution assembly, arranged adjacent to the process gas distribution assembly, the inert gas distribution assembly including a rectangular through-hole for supplying an inert gas to the substrate to be received on the substrate receiving surface from an upper side of the susceptor, the length in the longitudinal direction of the through-hole is longer than or equal with the diameter of the substrate to be received on the substrate receiving surface, the inert gas distribution assembly including a projecting part extending outwardly from the through-hole, wherein the inert gas distribution assembly is suspended from the ceiling part of the cartridge head and the rectangular through-hole extends toward the susceptor from an outer edge of the ceiling part through the ceiling part and through the projecting part of the inert gas distribution assembly; and
at least one of: (i) an additional process gas distribution assembly adjacent to the inert gas distribution assembly opposite the process gas distribution assembly; and (ii) an additional inert gas distribution assembly adjacent to the process gas distribution assembly opposite the inert gas distribution assembly; and
a gas exhausting system including a gas exhausting aperture defined between the gas distribution assemblies adjacent to each other, the gas exhausting system including an exhausting buffer, partly defined by the upper walls of the projecting parts, the ceiling part and side walls of the gas distribution assemblies adjacent to each other,
wherein the gas exhausting system is configured to exhaust a gas being in the domain sandwiched between the bottom surface of projecting part and the corresponding region of susceptor, through the corresponding exhausting buffer via the gas exhausting aperture.

2. The substrate processing apparatus according to claim 1, further including a rotary driving mechanism so as to move the relative position between the substrate to be received on the substrate receiving surface and the process or inert gas distribution assembly having a fan-shaped or trapezoid-shaped undersurface spreading for the outside from the pivot side.

3. The substrate processing apparatus according to claim 2, wherein the process gas distribution assembly or the inert gas distribution assembly is arranged so that the undersurface of each gas distribution assembly is parallel to the substrate receiving surface of the susceptor.

4. The substrate processing apparatus according to claim 3, wherein the width of the gas exhausting buffer in the rotatory direction is increased gradually or step by step from the inner side to the outer side of the radial direction of the gas exhausting buffer.

5. The substrate processing apparatus according to claim 2, wherein the gas exhausting system is configured to flow gases with a different conductance between the inner side and the outer side of the gas exhausting aperture or the gas exhausting buffer in the radial direction.

6. The substrate processing apparatus according to claim 5, wherein the exhaust buffer is formed so that the height of exhausting buffer is changed continuously or step by step from the inner side to outer side in the radial direction of exhausting buffer.

7. The substrate processing apparatus according to claim 5, wherein the gas exhausting system is configured so that the distance from the gas exhaust aperture to the exhaust buffer is changed continuously or step by step from the inner side to outer side in the radial direction of the gas exhausting system.

8. (canceled)

9. A substrate processing apparatus comprising:
a susceptor configured to receive a substrate on a substrate receiving surface of the susceptor;
a cartridge head disposed at the upper side of the susceptor, including a ceiling part;
a plurality of gas distribution assemblies comprising:
a first gas distribution assembly including a rectangular through-hole for supplying a first gas to the substrate to be received on the substrate receiving surface from an upper side of the susceptor and a projecting part extending outwardly from the through-hole, wherein the first gas distribution assembly is suspended from the ceiling part of the cartridge head and the rectangular through-hole extends toward the susceptor from an outer edge of the ceiling part through the ceiling part and through the projecting part of the first gas distribution assembly;
a second gas distribution assembly, arranged adjacent to the first gas distribution assembly, the second gas distribution assembly including a rectangular through-hole for supplying the second gas to the substrate to be received on the substrate receiving surface from an upper side of the susceptor and a projecting part extending outwardly from the through-hole to flow the second gas horizontally, wherein the second gas distribution assembly is suspended from the ceiling part of the cartridge head and the rectangular through-hole extends toward the susceptor from an outer edge of the ceiling part through the ceiling part and through the projecting part of the second gas distribution assembly; and
a third gas distribution assembly adjacent to the first gas distribution assembly or the second gas distribution assembly and opposite the other of the first gas distribution assembly and the second gas distribution assembly; and
a gas exhausting system including a gas exhausting aperture defined between the gas distribution assemblies adjacent to each other, the gas exhausting system including an exhausting buffer, partly defined by the upper walls of the projecting parts, the ceiling part and side walls of the gas distribution assemblies adjacent to each other,
wherein the gas exhausting system is configured to exhaust a gas being in the domain sandwiched between the bottom surface of projecting part and the corresponding region of susceptor, through the corresponding exhausting buffer via the gas exhausting aperture.

10. A substrate processing apparatus according to claim 9, wherein each length in the longitudinal direction of the through-hole of the gas distribution assemblies is longer than or equal with the diameter of the substrate to be received on the substrate receiving surface.

11. The substrate processing apparatus according to claim 10, wherein the width of the gas exhausting buffer in the rotatory direction is increased gradually or step by step from the inner side to the outer side of the radial direction of the gas exhausting buffer.

12. The substrate processing apparatus according to claim 9, further including a rotary driving mechanism so as to move the relative position between the substrate to be received on the substrate receiving surface and the first or second gas distribution assembly having a fan-shaped or trapezoid-shaped undersurface spreading for the outside from the pivot side.

13. The substrate processing apparatus according to claim 12, wherein the first gas distribution assembly or the second gas distribution assembly is arranged so that the undersurface of each gas distribution assembly is parallel to the substrate receiving surface of the susceptor.

14. The substrate processing apparatus according to claim 13, wherein the cartridge head is further including an outer cylindrical member extended down from outer edge of the ceiling part, the outer cylindrical member having a gas exhausting port, and an inner cylindrical member disposed at an inside of the outer cylindrical member, an inner cylindrical member having an exhausting hole corresponding to the exhausting buffer.
